(19) United States
(12) Patent Application Publication
(10) Pub. No.: US 2026/0182002 A1
(43) Pub. Date: Jun. 25, 2026

(54) SOURCE/DRAIN PATTERNING TECHNIQUES FOR STACKED DEVICE STRUCTURES

(71) Applicant: Taiwan Semiconductor Manufacturing Company, Ltd., Hsin-Chu (TW)

(72) Inventors: Chien-Lin YU, Miaoli County (TW); Zhi-Chang LIN, Hsinchu County (TW); Kuan-Kan HU, Hsinchu (TW); Tsung-Kai CHIU, Hsinchu County (TW)

(21) Appl. No.: 19/217,121

(22) Filed: May 23, 2025

Related U.S. Application Data
(60) Provisional application No. 63/737,249, filed on Dec. 20, 2024.

(51) Int. Cl. H10D 84/01; H10D 84/85

(52) U.S. Cl. CPC H10D 84/017; H10D 84/0188; H10D 84/851; H10D 84/856

(57) ABSTRACT

An exemplary method includes receiving a stacked structure that includes a first multilayer stack, a second multilayer stack, and a first insulation structure; forming a first portion of a source/drain trench in the first multilayer stack; after forming dummy sidewall masks in the first portion of the source/drain trench, extending the source/drain trench into the first insulation structure and the second multilayer stack, such that a second portion of the source/drain trench is in the first insulation structure and a third portion of the source/drain trench is in the second multilayer stack; forming a first source/drain in the third portion of the source/drain trench; after removing the dummy sidewall masks from the first portion of the source/drain trench, forming a second insulation structure in the second portion of the source/drain trench; and forming a second source/drain in the first portion of the source/drain trench.

This is a non-provisional application of and claims benefit of U.S. Provisional Patent Application Ser. No. 63/737,249, filed Dec. 20, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

As the semiconductor industry progresses into advanced IC technology nodes in pursuit of higher device density, higher performance, and lower costs, challenges from both a fabrication perspective and a design perspective have led to stacked transistor configurations, which have presented a new set of challenges. Improved fabrication techniques for stacked device structures, such as complementary transistor stacks, are thus needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a cross-sectional view of a stacked device structure, in portion or entirety, according to various aspects of the present disclosure.

FIG. 1B and FIG. 1C are cross-sectional views of the stacked device structure of FIG. 1A, in portion or entirety, according to various aspects of the present disclosure.

FIG. 2A is a flow chart of a method for preparing a stacked structure for use in fabricating a stacked device structure, such as the stacked device structure of FIGS. 1A-1C, according to various aspects of the present disclosure.

FIG. 2B is a flow chart of a method for fabricating a stacked device structure, such as the stacked device structure of FIGS. 1A-1C, from a stacked structure prepared by the method of FIG. 2A, according to various aspects of the present disclosure.

FIGS. 3A-3R are cross-sectional views of a stacked device structure, such as the stacked device structure of FIGS. 1A-1C, in portion or entirety, at various fabrication stages associated with the method of FIG. 2A and/or the method of FIG. 2B, according to various aspects of the present disclosure.

FIG. 4 is a cross-sectional view of a stacked device structure, such as the stacked structure of FIGS. 1A-1C, in portion or entirety, fabricated by the method of FIG. 2A and/or the method of FIG. 2B, according to various aspects of the present disclosure.

### DETAILED DESCRIPTION

The present disclosure relates generally to stacked device structures, such as transistor stacks having n-type transistors and p-type transistors (i.e., complementary field effect transistors (CFETs)), and more particularly, to source/drain stacks for stacked device structures.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Stacked device structures provide further density reduction for advanced integrated circuit (IC) technology nodes (particularly as they advance to 3 nm (N3) and below), especially when the stacked device structures include multigate devices, such as fin-like field effect transistors (FinFETs), gate-all-around (GAA) transistors including nanowires and/or nanosheets, other types of multigate devices, etc. Stacked device structures vertically stack devices, such as transistors. For example, a transistor stack may include a first transistor (e.g., a top transistor) disposed over a second transistor (e.g., a bottom transistor). The transistor stack may provide a complementary field effect transistor (CFET) when the first transistor and the second transistor are of opposite conductivity type (i.e., an n-type transistor and a p-type transistor).

The present disclosure is generally directed to source/drain patterning techniques for stacked device structures, such as stacked transistors. The disclosed source/drain patterning techniques may improve uniformity of device features (e.g., by reducing differences in heights/thicknesses of lower, bottom source/drains; reducing heights/thicknesses of upper, top source/drains; reducing variations in sidewall profiles of source/drain recesses and/or source/drains; or combinations thereof). The disclosed source/drain patterning techniques may improve device performance, for example, by improving uniformity. Different embodiments may have different advantages, and no particular advantage is required of any embodiment.

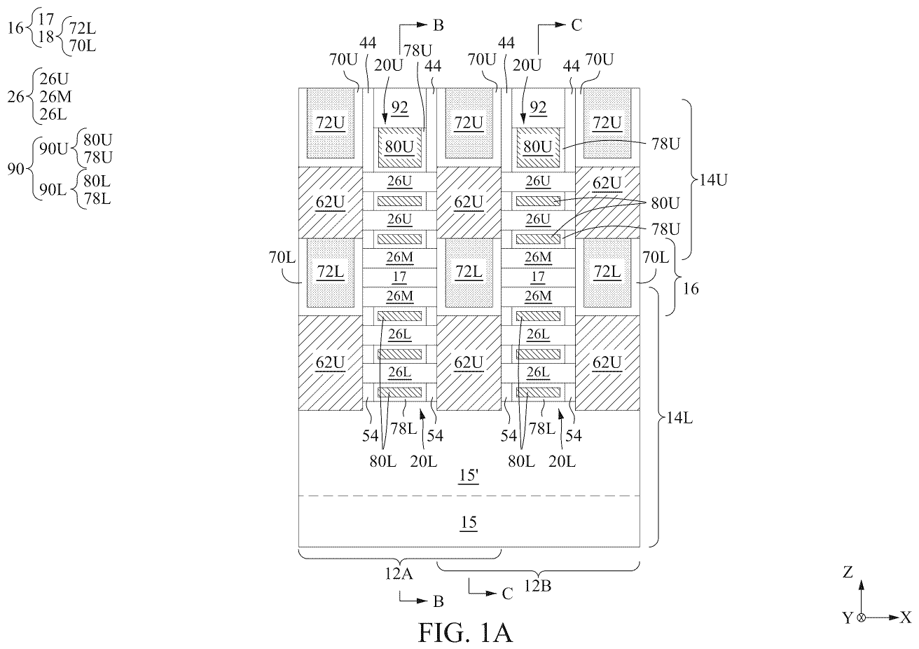

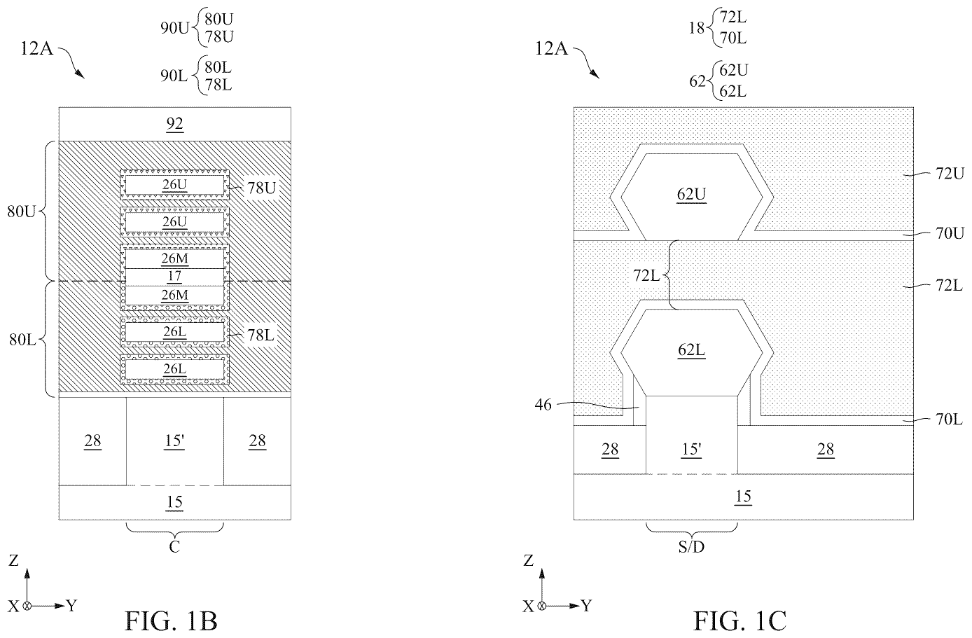

FIG. 1A is a cross-sectional view of a stacked device structure 10, in portion or entirety, according to various aspects of the present disclosure. FIG. 1B and FIG. 1C are cross-sectional views of stacked device structure 10, in portion or entirety, along line B-B and line C-C, respectively, of FIG. 1A according to various aspects of the present disclosure. Stacked device structure 10 includes a device stack 12A and a device stack 12B. Device stack 12A and device stack 12B each include a respective device (e.g., an upper transistor) of an upper device 14U and a respective device (e.g., a lower transistor) of a lower device 14L. Device 14U and device 14L are disposed over a substrate 15, and an isolation structure 16 is disposed between device 14U and device 14L. Isolation structure 16 includes isolation structures 17 and isolation structures 18. In some embodiments, device 14U and device 14L are stacked back-to-front. For example, isolation structure 16 (e.g., isolation structures 17 thereof) may bond and/or attach a backside of device 14U to a frontside of device 14L. In such example, isolation structure 16 (and/or isolations structures 17 thereof) may be referred to as an isolation/bonding structure. Stacked device structure 10 may be fabricated monolithically and referred to as a monolithic stacked device structure. FIGS. 1A-1C have been simplified for the sake of clarity to better understand the inventive concepts of the present disclosure. Additional features may be added in stacked device structure 10, and some of the features described below may be replaced, modified, or eliminated in other embodiments of stacked device structure 10.

Referring to FIGS. 1A-1C, device 14U includes at least one electrically functional device, such as transistors 20U, and device 14L includes at least one electrically functional device, such as transistors 20L. Accordingly, device stack 12A may be a transistor stack having a respective upper transistor 20U and a respective lower transistor 20, and device stack 12B may be a transistor stack having a respective upper transistor 20U and a respective lower transistor 20. Transistors 20U may be separated and/or electrically isolated from respective transistors 20L by isolation structure 16. In the depicted embodiment, transistors 20U and transistors 20L are of an opposite conductivity type. For example, transistors 20U are n-type transistors, and transistors 20L are n-type transistors, or vice versa. In such embodiments, the transistor stacks (e.g., having a respective transistor 20U and a respective transistor 20L) form CFETs. Device stack 12A and device stack 12B may thus be referred to as CFETs. In some embodiments, transistors 20U and transistors 20L are of a same conductivity type. For example, transistors 20U and transistors 20L are both configured as n-type transistors or both p-type transistors.

Device 14U includes various features and/or components, such as semiconductor layers 26U, semiconductor layers 26M, gate spacers 44, inner spacers 54, source/drains 62U, a contact etch stop layer (CESL) 70U, an interlayer dielectric (ILD) layer 72U, gate dielectrics 78U, gate electrodes 80U, and hard masks 92. A respective gate dielectric 78U and a respective gate electrode 80U collectively form an upper gate stack 90U. Device 14L includes various features and/or components, such as protrusions 15′ (which may be extensions of substrate 15), semiconductor layers 26L, semiconductor layers 26M, substrate isolation structures 28, fin spacers 46, inner spacers 54, source/drains 62L, a CESL 70L, an ILD layer 72L, gate dielectrics 78L, and gate electrodes 80L. A respective gate dielectric 78L and a respective gate electrode 80L collectively form a lower gate stack 90L. A respective gate stack 90U and a respective gate stack 90L are collectively referred to as a gate 90 (or gate stack) of a device stack (e.g., device stack 12A or device stack 12B), and gate 90 may provide a metal gate or a high-k/metal gate of a CFET. In some embodiments, gate stack 90U is separated from gate stack 90L by a respective isolation structure 17 (and semiconductor layers 26M, in the depicted embodiment), and source/drains 62L are separated from source/drains 62U by isolation structures 18. For ease of description herein, semiconductor layers 26U, semiconductor layers 26M, and semiconductor layers 26L may be referred to collectively as semiconductor layers 26.

Transistors 20L are configured as GAA transistors. For example, each of transistors 20L may include two channels (e.g., nanowires, nanosheets, nanobars, etc.) provided by semiconductor layers 26L (also referred to as channel layers or channels), which are suspended over substrate 15 and extend between respective source/drains (e.g., source/drains 62L). In some embodiments, transistors 20L may include more or less channels (and thus more or less semiconductor layers 26L). Each transistor 20L has a respective gate stack 90L disposed over its semiconductor layers 26L and between its source/drains 62L. Along a gate widthwise direction (FIG. 1A), the respective gate stack 90L may be over a respective top semiconductor layer 26L, between respective semiconductor layers 26L, and between a respective bottom semiconductor layer 26L and substrate 15 (e.g., protrusion 15′ thereof). Along a gate lengthwise direction (FIG. 1B), the respective gate stack 90L wraps around respective semiconductor layers 26L. During operation of the GAA transistors, current may flow through respective semiconductor layers 26L and between respective source/drains 62L. In the depicted embodiment, transistors 20L of adjacent device stacks, such as of device stack 12A and device stack 12B, have a common source/drain 62L, such as middle source/drain 62L depicted in FIG. 1A. In some embodiments, transistors 20L do not have a common source/drain 62L. Each of transistors 20L may further include semiconductor layers 26M (also referred to as dummy channel layers or dummy channels) suspended over substrate 15 and extending between respective isolation structures 18, and each device stack may include a respective isolation structure 17 disposed between semiconductor layer 26M of its respective transistor 20L and semiconductor layer 26M of its respective transistor 20U. Further, each of transistors 20L may include inner spacers 54 disposed between its gate stack (e.g., gate stack 90L) and its source/drains 62L.

Transistors 20U are also configured as GAA transistors. For example, each of transistors 20U may include two channels (e.g., nanowires, nanosheets, nanobars, etc.) provided by semiconductor layers 26U (also referred to as channel layers or channels), which are suspended over substrate 15 and extend between respective source/drains (e.g., source/drains 62U). In some embodiments, transistors 20U include more or less channels (and thus more or less semiconductor layers 26U). Each transistor 20U has a respective gate stack 90U disposed over its semiconductor layers 26U and between its source/drains 62U. Along a gate widthwise direction (FIG. 1A), the respective gate stack 90U may be over a respective top semiconductor layer 26U, between respective semiconductor layers 26U, and between a respective bottom semiconductor layer 26U and a respective semiconductor layer 26M. Along a gate lengthwise direction (FIG. 1B), the respective gate stack 90U wraps around respective semiconductor layers 26U. During operation of the GAA transistors, current may flow through respective semiconductor layers 26U and between respective source/drains 62U. In the depicted embodiment, transistors 20U of adjacent device stacks, such as of device stack 12A and device stack 12B, have a common source/drain 62U, such as middle source/drain 62U depicted in FIG. 1A. In some embodiments, transistors 20U do not have a common source/drain 62U. Each of transistors 20U may further include semiconductor layers 26M (i.e., dummy channel layers) suspended over substrate 15 and extending between respective isolation structures 18. Further, transistors 20U may each include gate spacers 44 disposed along sidewalls of an upper portion of its gate stack (e.g., gate stack 90U), inner spacers 54 disposed between its gate stack and its source/drains 62U, and hard masks 92 disposed over its gate stack and between its gate spacers 44. Hard masks 92 may be considered a portion of the gate stacks.

Isolation structure 16 includes isolation structures 17 and isolation structures 18 between channel regions and source/drain regions, respectively, of device 14L and device 14U. For example, isolation structures 17 are between channel regions of lower transistors (e.g., transistors 20L) and channel regions of upper transistors (e.g., transistors 20U) (e.g., between channels and/or gates thereof), and isolation structures 18 are between source/drain regions of lower transistors (e.g., transistors 20L) and source/drain regions of upper transistors (e.g., transistors 20U). In the depicted embodiment, isolation structures 17 are between semiconductor layers 26M of lower transistors and upper transistors, and isolation structures 18 are between source/drains 62L of lower transistors and source/drains 62U of upper transistors. Accordingly, isolation structures 17 may provide electrical isolation of channels and/or gates of stacked devices, and isolation structures 18 may provide electrical isolation of source/drains of stacked devices. Isolation structures 17 and isolation structures 18 may include a single layer or multiple layers. Isolation structures 17 and isolation structures 18 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, etc.). Isolation structures 17 and isolation structures 18 may include the same or different materials and/or configurations. In the depicted embodiment, a thickness of isolation structures 17 is less than a thickness of isolation structures 18, and a configuration of isolation structures 17 is different than a configuration of isolation structures 18. In some embodiments, isolation structures 18 include CESL 70L and ILD layer 72L, such as depicted (i.e., each isolation structure 18 is formed by a respective portion of CESL 70L and a respective portion of ILD layer 72L). In some embodiments, such as those described below, a thickness of isolation structures 17 is substantially the same as (i.e., about equal to) a thickness of isolation structures 18, and a configuration of isolation structures 17 is different than a configuration of isolation structures 18.

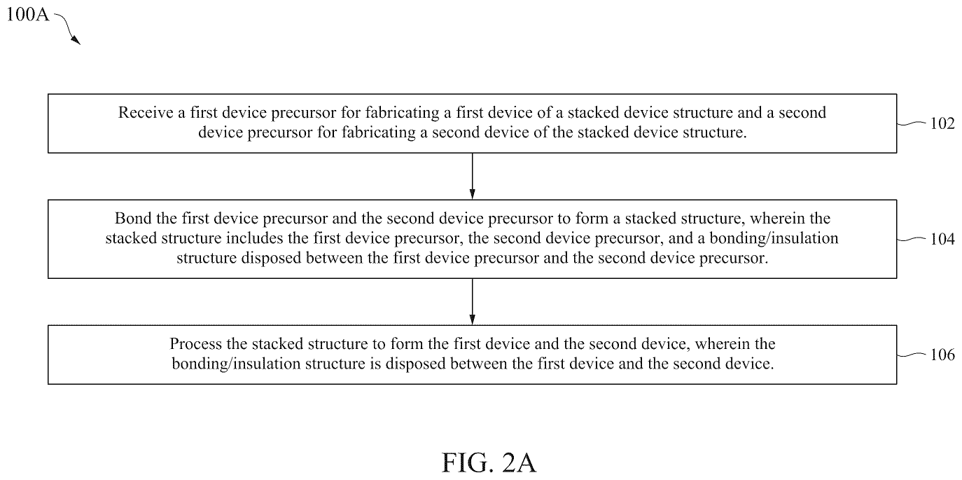

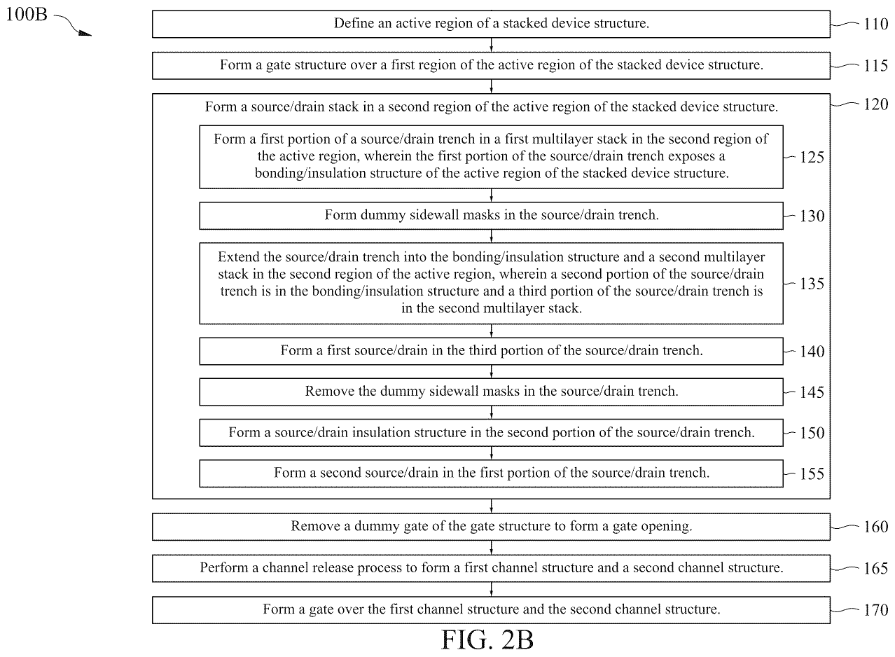

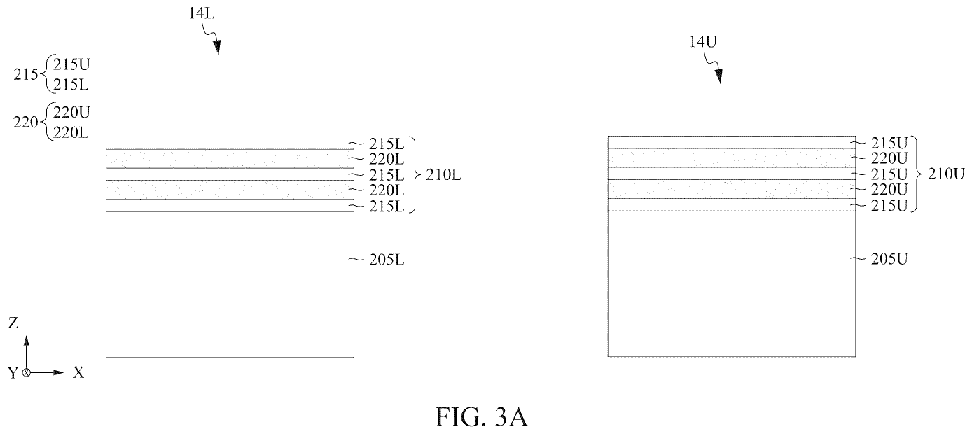

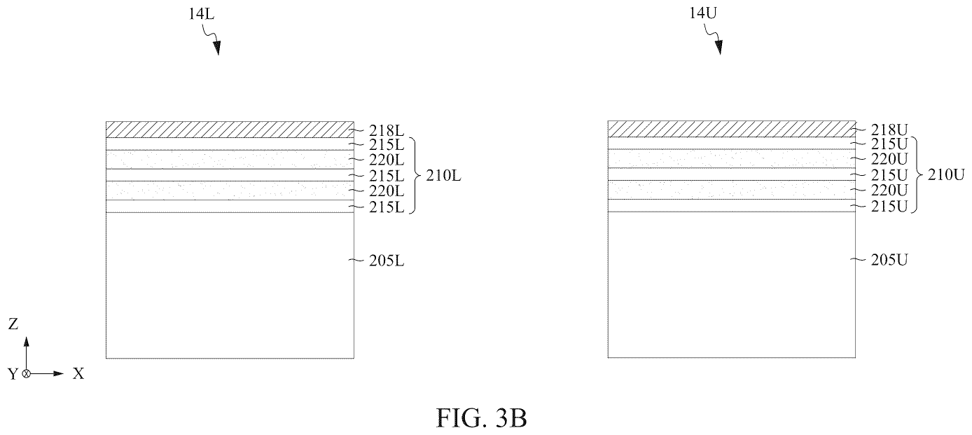

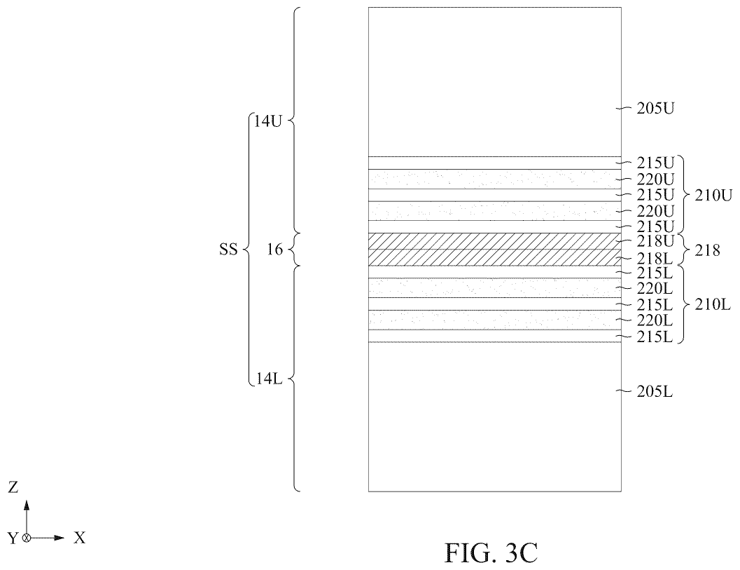

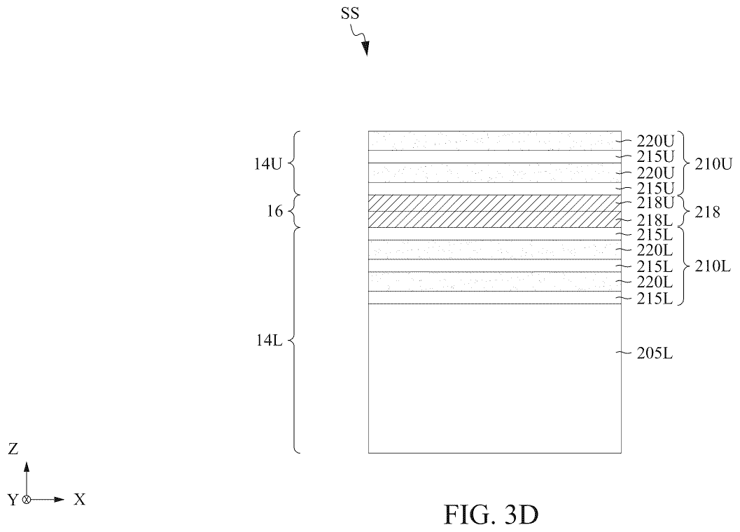

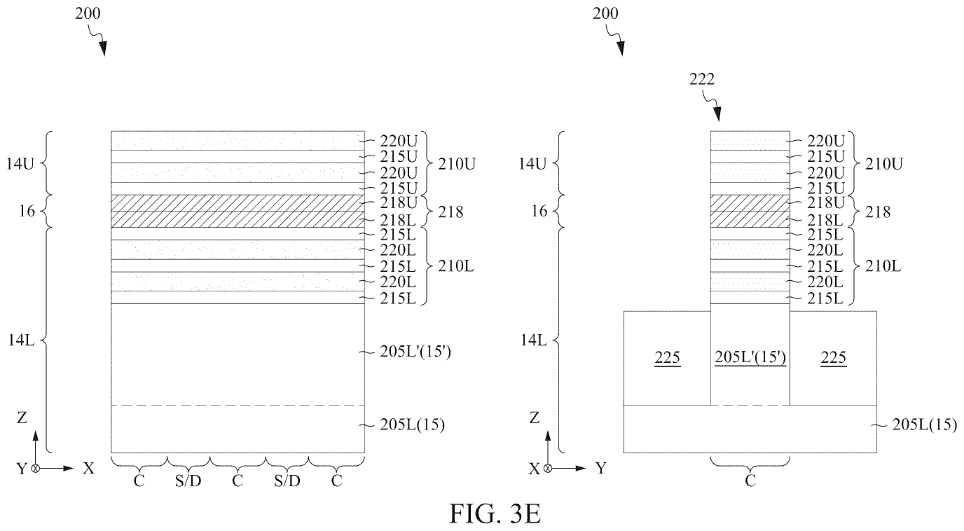

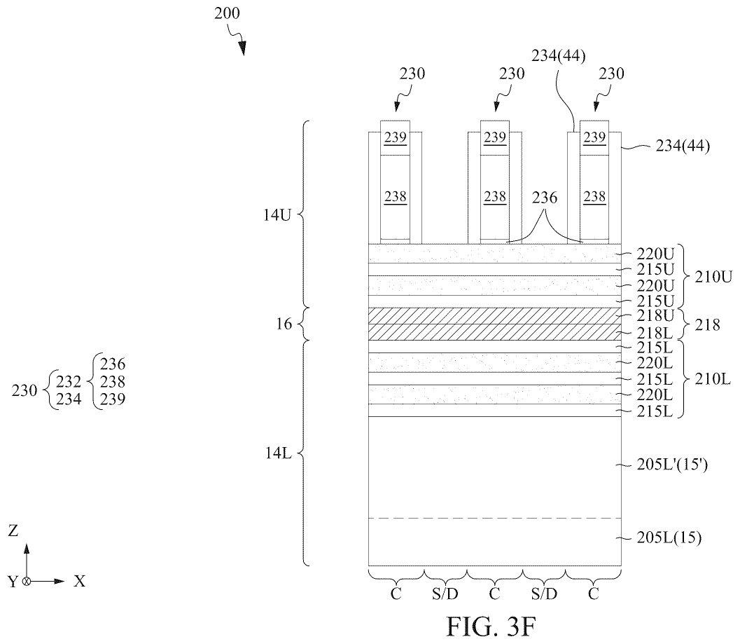

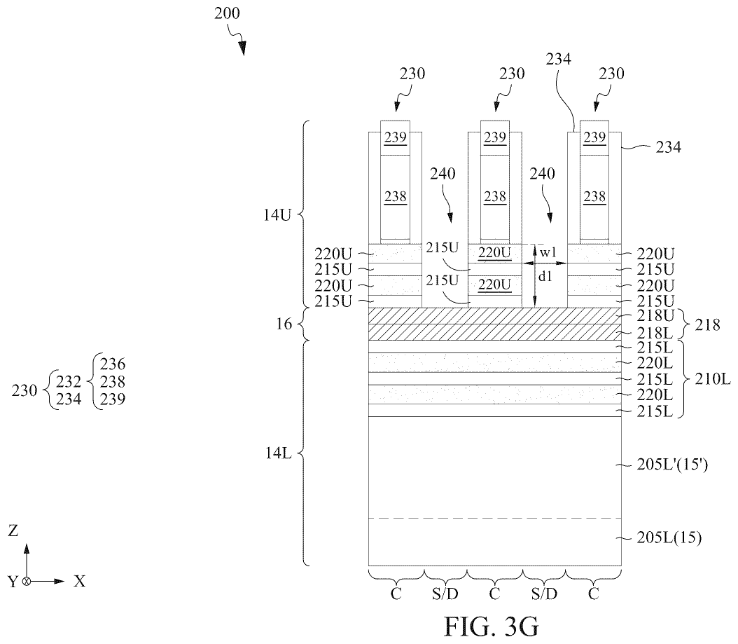

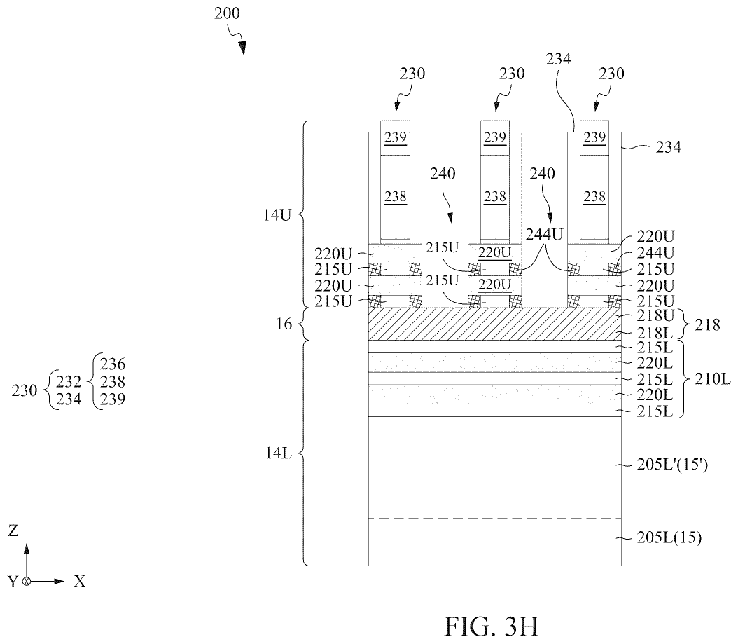

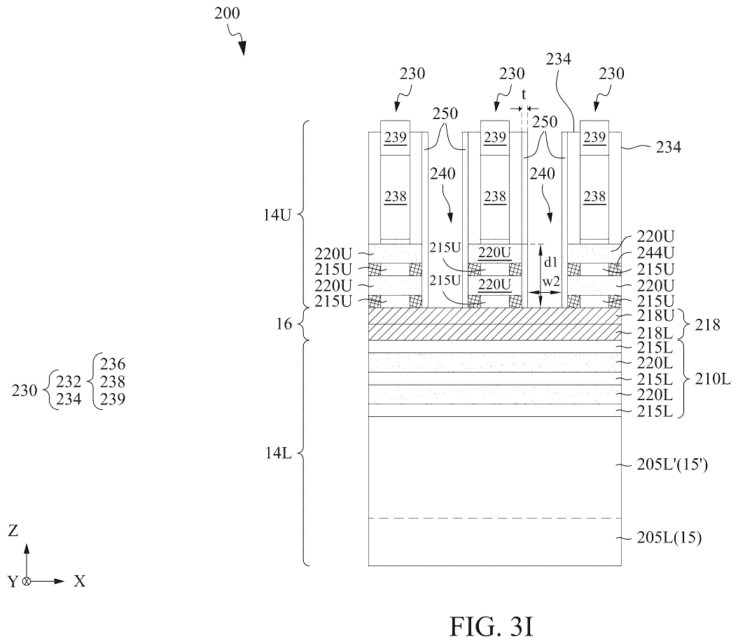

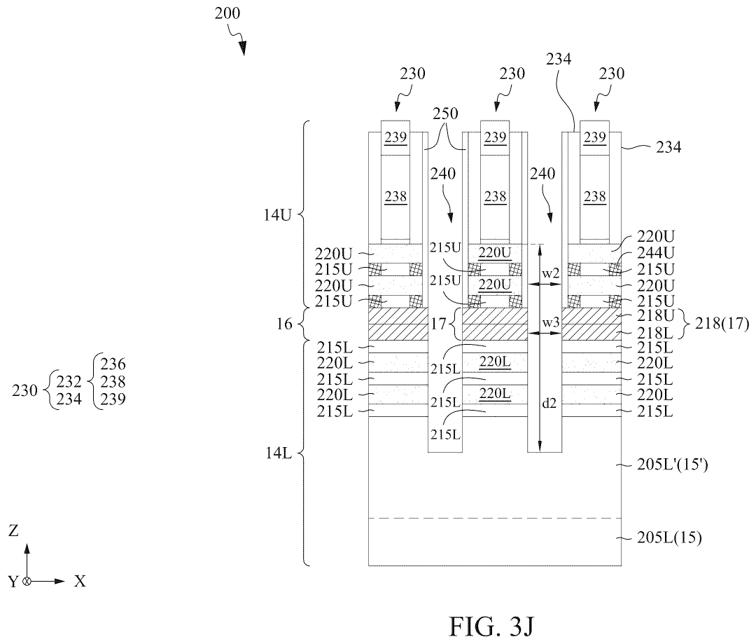

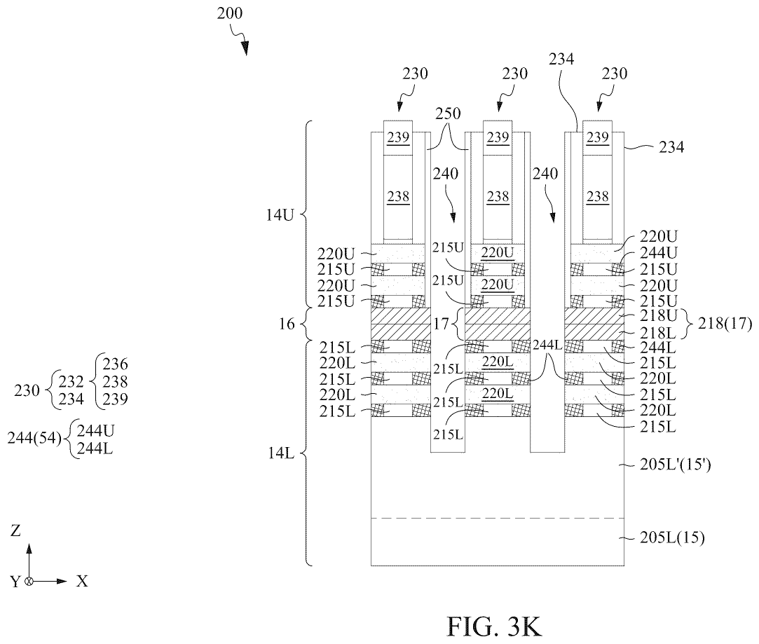

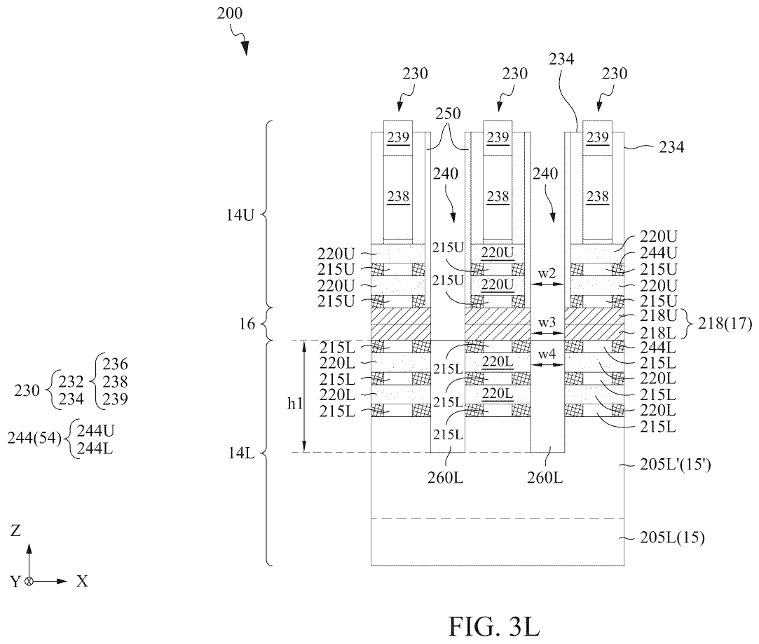

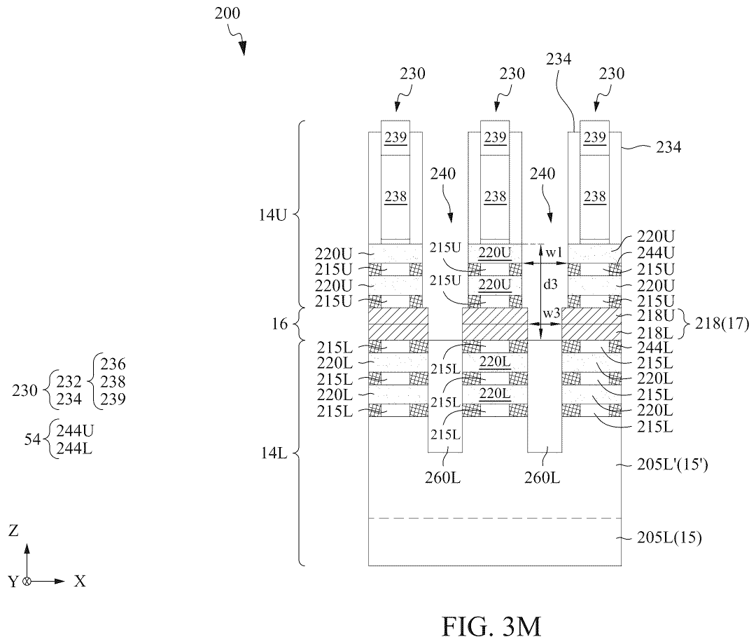

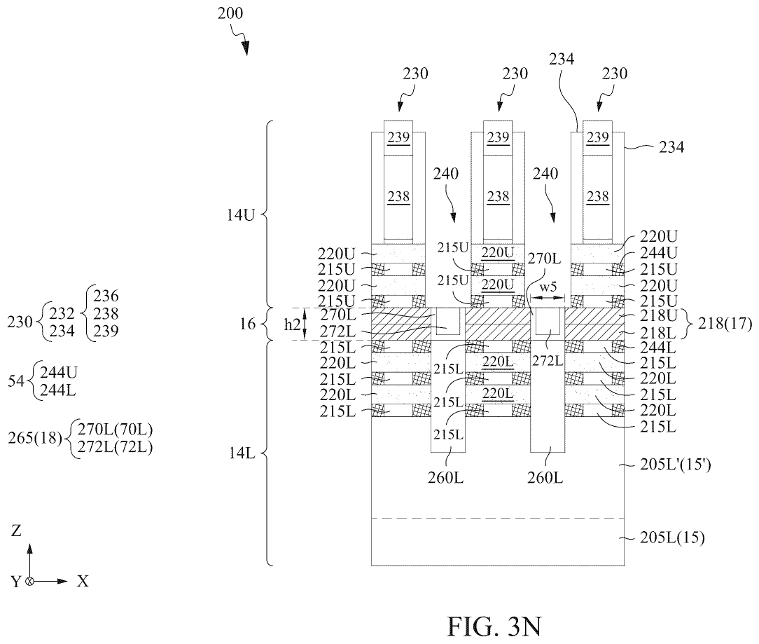

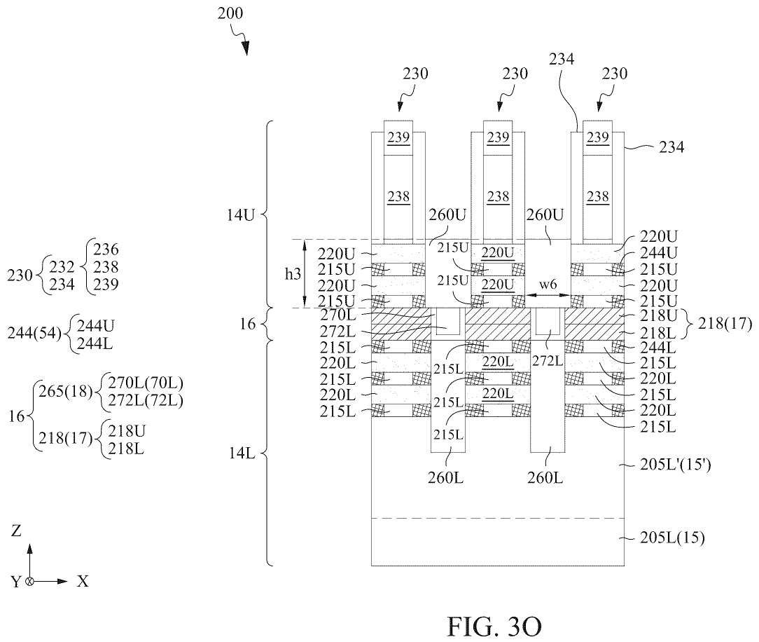

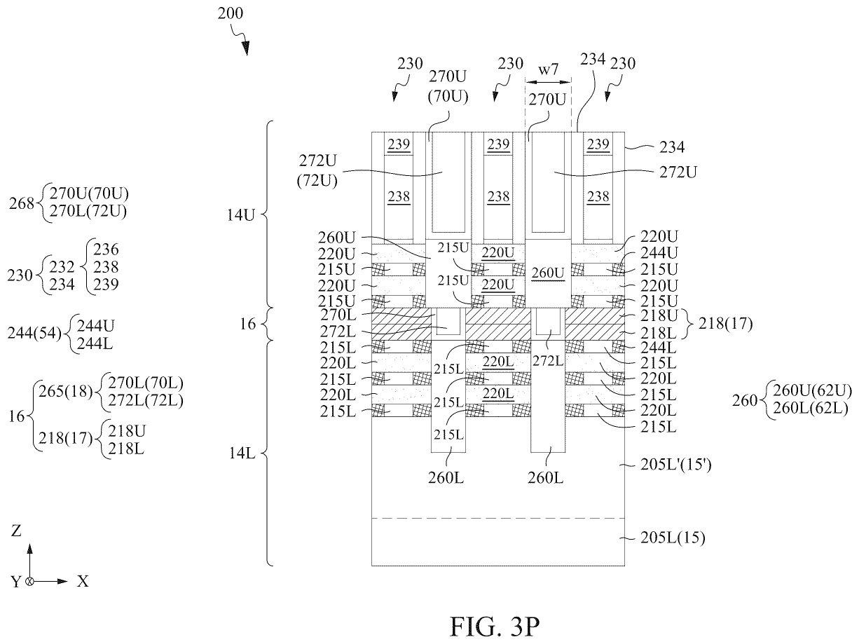

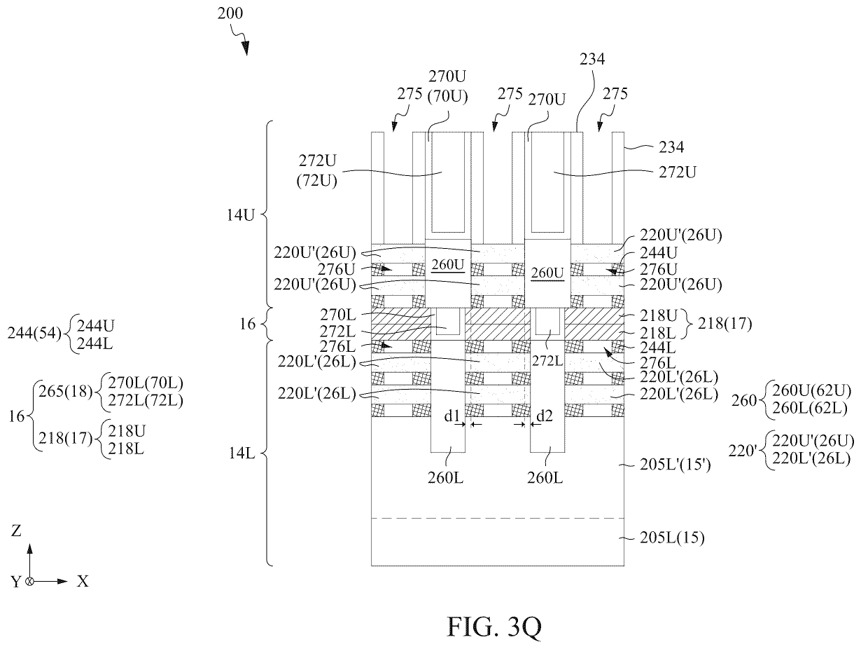

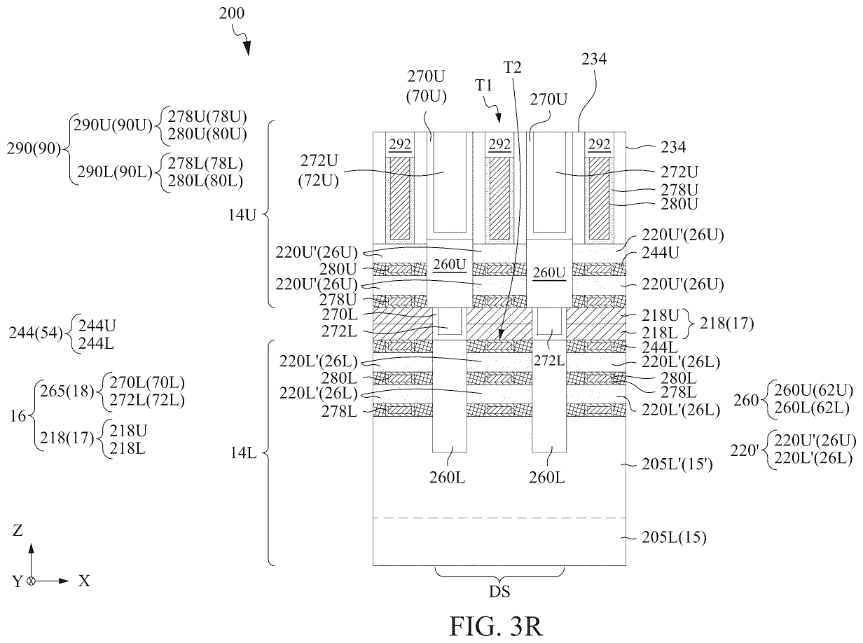

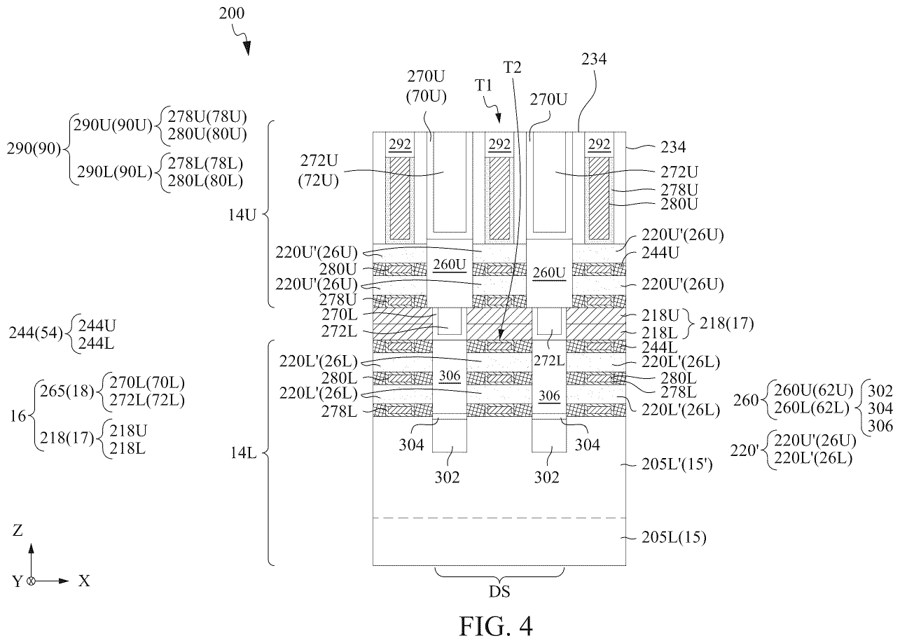

FIG. 2A is a flow chart of a method 100A for preparing a stacked structure for use in fabricating a stacked device structure, such as the stacked device structure of FIGS. 1A-1C, according to various aspects of the present disclosure. FIG. 2B is a flow chart of a method 100B for fabricating a stacked device structure, such as the stacked device structure of FIGS. 1A-1C, from a stacked structure, such as that prepared by method 100A of FIG. 2A, according to various aspects of the present disclosure. FIGS. 3A-3R are cross-sectional views of a stacked device structure 200 (which may be and/or is similar to stacked device structure of FIGS. 1A-1C), in portion or entirety, at various fabrication stages of method 100A of FIG. 2A and method 100B of FIG. 2B, according to various aspects of the present disclosure. For example, FIGS. 3A-3D are cross-sectional views of a stacked structure SS, in portion or entirety, at various fabrication stages associated with method 100A of FIG. 2A, according to various aspects of the present disclosure, and FIGS. 3E-3R are cross-sectional views of a stacked device structure 200, in portion or entirety, at various fabrication stages associated with method 100B of FIG. 2B, according to various aspects of the present disclosure. Method 100A and method 100B, described with reference to FIGS. 3A-3R, implement a source/drain fabrication technique that may reduce process variations, thereby improving device uniformity and/or device performance. FIGS. 3A-3R are taken (cut) along a gate widthwise direction (e.g., an x-direction), like the cross-sectional view of FIG. 1A. Further, since stacked device structure 200 is similar in many respects to stacked device structure 10, similar features of stacked device structure 200 and stacked device structure 10 are identified by the same reference numerals for clarity and simplicity. FIG. 4 is another cross-sectional view of stacked device structure 200, in portion or entirety, which may be fabricated according to method 100A of FIG. 2A and method 100B of FIG. 2B, according to various aspects of the present disclosure. FIG. 2A, FIG. 2B, FIGS. 3A-3R, and FIG. 4 have been simplified for the sake of clarity to better understand the inventive concepts of the present disclosure. Additional steps can be provided before, during, and after method 100A and/or method 100B, and some of the steps described can be moved, replaced, or eliminated for additional embodiments of method 100A and/or method 100B. Additional features may be added in the stacked device structure of FIGS. 3A-3R and/or FIG. 4, and some of the features described below can be replaced, modified, or eliminated in other embodiments of the stacked device structure of FIGS. 3A-3R and/or FIG. 4.

Referring to FIG. 2A and FIG. 3A, method 100A at block 102 includes receiving and/or forming a first device precursor for fabricating a first device (e.g., an upper device, such as device 14U and/or transistor 20U) of a stacked device structure (e.g., stacked device structure 200) and a second device precursor for fabricating a second device (e.g., a lower device, such as device 14L and/or transistor 20L) of the stacked device structure. In the depicted embodiment, each of the first device precursor and the second device precursor include a respective substrate and a respective multilayer stack. For example, the first device precursor includes a substrate 205U and a multilayer stack 210U, and the second device precursor includes a substrate 205L and a multilayer stack 210L. Multilayer stack 210U is disposed over substrate 205U, and multilayer stack 210L is disposed over substrate 205L. In the depicted embodiment, multilayer stack 210U includes sacrificial layers 215U and semiconductor layers 220U, and multilayer stack 210L includes sacrificial layers 215L and semiconductor layers 220L.

Substrate 205U and/or substrate 205L includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 205U and substrate 205L are silicon substrates. In some embodiments, substrate 205U and/or substrate 205L is a semiconductor-on-insulator substrate, such as a silicon-on-insulator (SOI) substrate, a silicon germanium-on-insulator (SGOI) substrate, or a germanium-on-insulator (GOI) substrate. Substrate 205U and/or substrate 205L may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include combinations of p-type dopants and n-type dopants.

Sacrificial layers 215U and semiconductor layers 220U are stacked vertically (e.g., along a z-direction) in an interleaving and/or alternating configuration over substrate 205U, and sacrificial layers 215L and semiconductor layers 220L are stacked vertically in an interleaving and/or alternating configuration over substrate 205L. A composition of sacrificial layers 215 (collectively referring to sacrificial layers 215U and sacrificial layers 215L) is different than a composition of semiconductor layers 220 (collectively referring to semiconductor layers 220U and semiconductor layers 220L), for example, to achieve etch selectivity therebetween. For example, sacrificial layers 215 and semiconductor layers 220 include different materials, constituent atomic percentages, constituent weight percentages, other characteristics, or combinations thereof. In some embodiments, sacrificial layers 215 include silicon germanium, and semiconductor layers 220 include silicon. In some embodiments, sacrificial layers 215 and semiconductor layers 220 include the same material but with different constituent atomic percentages. For example, sacrificial layers 215 and semiconductor layers 220 may both include silicon germanium, but with different germanium atomic percentages. Sacrificial layers 215 and semiconductor layers 220 may include any combination of materials that provides desired etching selectivity, oxidation rate differences, performance characteristics (e.g., materials that maximize current flow), other desired characteristics, or combinations thereof.

Semiconductor layers 220 or portions thereof may form channels of transistors. In the depicted embodiment, multilayer stack 210U and multilayer stack 210L each include three sacrificial layers 215 and two semiconductor layers 220. After processing of multilayer stack 210U and multilayer stack 210L (such as that described herein), this configuration may result in transistors having two channels. In some embodiments, multilayer stack 210U and/or multilayer stack 210L includes different numbers of sacrificial layers 215 and/or semiconductor layers 220 depending, for example, on a number of channels desired for the transistors. For example, multilayer stack 210U and/or multilayer stack 210L may include two to six semiconductor layer pairs, each of which has a respective sacrificial layer 215 and a respective semiconductor layer 220. Further, sacrificial layers 215L and sacrificial layers 215U may have the same or different compositions, and semiconductor layers 220L and semiconductor layers 220U may have the same or different compositions, for example, depending on their respective device's configuration (e.g., as an n-type transistor or a p-type transistor).

Multilayer stack 210U may be formed by depositing sacrificial layers 215U and semiconductor layers 220U over substrate 205U in the depicted interleaving and/or alternating configuration, and multilayer stack 210L may be formed by depositing sacrificial layers 215L and semiconductor layers 220L over substrate 205L in the depicted interleaving and/or alternating configuration. In some embodiments, the depositing includes epitaxially growing sacrificial layers 215 and semiconductor layers 220. For example, a first one of sacrificial layers 215 is epitaxially grown over a respective substrate, a first one of semiconductor layers 220 is epitaxially grown on the first one of sacrificial layers 215, a second one of sacrificial layers 215 is epitaxially grown on the first one of semiconductor layers 220, and so on until multilayer stack 210U and/or multilayer stack 210L has a desired number of sacrificial layers 215 and a desired number of semiconductor layers 220. In such embodiments, sacrificial layers 215 and semiconductor layers 220 may be referred to as epitaxial layers, and the multilayer stacks may be referred to as epitaxial stacks. Epitaxial growth of sacrificial layers 215 and semiconductor layers 220 is provided by molecular beam epitaxy (MBE), chemical vapor deposition (CVD), metalorganic CVD (MOCVD), other epitaxial growth process, or combinations thereof.

Referring to FIG. 2A, FIG. 3B, and FIG. 3C, method 100A at block 104 includes bonding the first device precursor and the second device precursor to form a stacked structure (e.g., stacked structure SS). The stacked structure includes the first device precursor (e.g., multilayer stack 210U over substrate 205U), the second device precursor (e.g., multilayer stack 210L over substrate 205L), and a bonding/insulation structure (e.g., bonding/insulation structure 16) disposed between the first device precursor and the second device precursor.

Referring to FIG. 3B, a bonding layer 218U may be formed over multilayer stack 210U (e.g., on topmost sacrificial layer 215U thereof) of the first device precursor (e.g., for fabricating device 14U), and a bonding layer 218L may be formed over multilayer stack 210L (e.g., on topmost sacrificial layer 215L thereof) of the second device precursor (e.g., for fabricating device 14L). In some embodiments, bonding layer 218U has a thickness of about 5 nm to about 10 nm and/or bonding layer 218L has a thickness of about 5 nm to about 10 nm. Bonding layer 218U and bonding layer 218L include electrically insulating material(s) that facilitates bonding therebetween, and thus facilitates bonding of multilayer stack 210U and multilayer stack 210L. In some embodiments, bonding layer 218U and bonding layer 218L include materials that facilitate dielectric-to-dielectric bonding and electrically isolation of the first device precursor and the second device precursor. In some embodiments, bonding layer 218U and/or bonding layer 218L include silicon and oxygen, nitrogen, carbon, or combinations thereof (e.g., silicon oxide (e.g., SiO₂), silicon nitride (SiN), silicon oxynitride (SiON), silicon carbonitride (SiCN), silicon oxycarbide (SiOC), silicon oxycarbonitride (SiOCN), etc.). In some embodiments, bonding layer 218U and/or bonding layer 218L include boron and oxygen, nitrogen, carbon, or combinations thereof (e.g., boron nitride (BN), boron carbonitride (BCN), etc.). In some embodiments, bonding layer 218U and/or bonding layer 218L include metal and oxygen, nitrogen, carbon, or combinations thereof (e.g., aluminum oxide (Al₂O₃), aluminum nitride (AlN), hafnium oxide (HfO₂), yttrium oxide (Y₂O₃), etc.).

Referring to FIG. 3C, the bonding may include flipping over the first device precursor (e.g., for fabricating device 14U), aligning the first device precursor with the second device precursor (e.g., for fabricating device 14L), and attaching the first device precursor to the second device precursor, thereby providing stacked structure SS. For example, the bonding includes bringing bonding layer 218U of the first device precursor into contact with bonding layer 218L of the second device precursor (or vice versa). Bonding layer 218U and bonding layer 218L may be brought into contact under a temperature, a pressure, an atmosphere, or combinations thereof for a time that effectuates bonding of bonding layer 218U and bonding layer 218L. For example, a given bonding pressure and/or a given bonding temperature may be applied to the first device precursor, bonding layer 218U thereof, the second device precursor, bonding layer 218L thereof, or combinations thereof for a given bonding time to effectuate chemical bonding/adhesion of bonding surfaces of bonding layer 218U and bonding layer 218L.

In some embodiments, the first device precursor and the second precursor are heterogeneously bonded, and bonding layer 218U and bonding layer 218L include different dielectric materials. For example, bonding layer 218U may be an oxygen-containing dielectric layer (e.g., an oxide layer, such as silicon oxide), and bonding layer 218L may be a silicon-and-nitrogen-containing dielectric layer (e.g., a SiN layer, an SiON layer, or a SiCN layer) or a boron-and-nitrogen-containing dielectric layer (e.g., a BN layer or a BCN layer). In some embodiments, the first device precursor and the second precursor are homogenously bonded, and bonding layer 218U and bonding layer 218L include the same dielectric materials. For example, bonding layer 218U and bonding layer 218L may be silicon-and-nitrogen-containing dielectric layers (e.g., SiN layers, SiON layers, or SiCN layers) or boron-and-nitrogen-containing dielectric layers (e.g., BN layers or BCN layers). In such embodiments, a plasma activation process (e.g., an oxygen plasma treatment) may be performed on bonding layer 218U and bonding layer 218L before bringing bonding layer 218U into contact with bonding layer 218L (or vice versa). The plasma activation process may transform (e.g., oxidize) portions of bonding layer 218U and bonding layer 218L into plasma-activated portions/layers, such that bonding layer 218U and bonding layer 218L are provided with plasma-activated surfaces, and parameters of the bonding process may be configured to effectuate chemical bonding/adhesion of the plasma-activated surfaces of bonding layer 218U and bonding layer 218L. After bonding, in such embodiments, bonding/insulation structure 218 may include bonding layer 218U, bonding layer 218L, and a plasma-activated layer between bonding layer 218U and bonding layer 218L. The plasma activated layer may include the plasma activated portion (e.g., oxidized portion) of bonding layer 218U, the plasma activated portion (e.g., oxidized portion) of bonding layer 218L, and any combined portion of the plasma activated portions. In some embodiments, an atomic concentration of oxygen in the plasma activated layer is greater than an atomic concentration of oxygen in bonding layer 218U and an atomic concentration of oxygen in bonding layer 218L (i.e., the plasma activated layer is an oxygen-rich insulation layer). In some embodiments, the plasma activated layer is a silicon-and-oxygen containing layer disposed between silicon-and-nitrogen containing insulation layers (e.g., bonding layer 218U and bonding layer 218L may be SiN layers or SiCN layers). In some embodiments, the plasma activated layer is an oxygen-containing layer disposed between boron-and-nitrogen containing insulation layers (e.g., bonding layer 218U and bonding layer 218L are BN layers or BCN layers).

Referring to FIG. 3D, in some embodiments, a thinning process may be performed to remove substrate 205U from the first device precursor (e.g., for fabricating device 14U). For example, a planarization process, such as chemical mechanical polishing (CMP), or an etching process is performed to remove substrate 205U. In some embodiments, top sacrificial layer 215U of multilayer stack 210U functions as a planarization/CMP stop layer and/or an etch stop layer, and the planarization process and/or the etching process stops upon reaching top sacrificial layer 215U. In some embodiments, such as depicted, top sacrificial layer 215U may also be removed by a planarization process and/or an etching process, to expose top semiconductor layer 220 of multilayer stack 210U. In some embodiments, top semiconductor layer 220 functions as a planarization/CMP stop layer and/or an etch stop layer, and a planarization process and/or an etching process removes substrate 205U and top sacrificial layer 215U. In some embodiments, a combination of etching and polishing/planarization is implemented to remove substrate 205U and/or top sacrificial layer 215U. Other methods and/or techniques for removing substrate 205U and/or top sacrificial layer 215U are contemplated. In some embodiments, a de-bonding process may be performed to remove substrate 205U. In such embodiments, top sacrificial layer 215U may be removed by planarization after the de-bonding process.

After bonding and removal of substrate 205U, stacked structure SS includes the first device precursor (e.g., multilayer stack 210U) and the second device precursor (e.g., multilayer stack 210L and substrate 205L). The first device precursor is attached to, and electrically isolated from, the second device precursor by a bonding/insulation structure 218 between multilayer stack 210U and multilayer stack 210L. Bonding/insulation structure 218 includes bonding layer 218U, bonding layer 218L, and any layer formed therebetween by intermixing of and/or bonding of bonding layer 218U and bonding layer 218L. For example, when the first device precursor and the second device precursor are homogenously bonded, bonding/insulation structure 218 may include an oxygen-rich portion disposed between silicon-and-nitrogen containing portions (or boron-and-nitrogen containing portions). In another example, when the first device precursor and the second device precursor are heterogeneously bonded, bonding/insulation structure 218 may include an oxygen-containing portion and a silicon-and-nitrogen containing portion (or a boron-and-nitrogen containing portion).

Referring to FIG. 2A and FIGS. 3E-3R, method 100A at block 106 includes processing the stacked structure (e.g., stacked structure SS) to form the first device (e.g., device 14U and/or transistor 20U) and the second device (e.g., device 14L and/or transistor 20L), where the bonding/insulation structure (e.g., bonding/insulation structure 218) is disposed between the first device and the second device. In some embodiments, such as described below, stacked structure SS is provided for monolithically fabricating a transistor stack of stacked device structure 200. For example, the first device precursor and the second device precursor may be processed according to method 100B of FIG. 2B to form an upper transistor (e.g., transistor 20U) and a lower transistor (e.g., transistor 20L), respectively, of stacked device structure 200. In such example, bonding/insulation structure 218 provides an isolation structure between the lower transistor and the upper transistor, such as a portion of isolation structure 16 (e.g., isolation structures 17) between channel regions of the lower transistor and the upper transistor.

Referring to FIG. 2B and FIG. 3E, method 100B at block 110 may include defining and/or forming an active region (e.g., an active region 122) of a stacked device structure (e.g., stacked device structure 200). Active region 222 extends substantially along an x-direction, having a length along the x-direction, a width along a y-direction, and a height along a z-direction. Active region 222 may include channel regions (C), source regions, and drain regions, and the source regions and the drain regions may collectively be referred to as source/drain regions (S/D). In some embodiments, active region 222 is formed by patterning stacked structure SS. For example, a lithography process and/or an etching process patterns multilayer stack 210U, bonding/insulation structure 218, multilayer stack 210L, and substrate 205L, thereby providing active region 222 with an upper multilayer stack (e.g., portion of multilayer stack 210U), an isolation structure (e.g., portion of bonding/insulation structure 218), a lower multilayer stack (e.g., portion of multilayer stack 210L), and a protrusion 205L′ (e.g., portion of substrate 205L). In some embodiments, protrusion 205L′ is a patterned, projecting portion and/or extension of substrate 205L, and protrusion 205L′ may be referred to as a substrate extension, a substrate fin portion, a fin portion, an etched substrate portion, etc. In some embodiments, active region 222 is formed by a multiple patterning process, such as a double patterning lithography (DPL) process (e.g., a lithography-etch-lithography-etch (LELE) process, a self-aligned double patterning (SADP) process, a spacer-is-dielectric (SID) process, other double patterning process, or combinations thereof), a triple patterning process (e.g., a lithography-etch-lithography-etch-lithography-etch (LELELE) process, a self-aligned triple patterning (SATP) process, other triple patterning process, or combinations thereof), other multiple patterning process (e.g., self-aligned quadruple patterning (SAQP) process), or combinations thereof. In some embodiments, active region 222 is formed using directed self-assembly (DSA) techniques. In some embodiments, active region 222 is formed by a fin fabrication process. Active region 222 may thus be referred to as a fin, a fin structure, a fin element, an active fin region, a multilayer stacked structure, a multilayer stack, etc.

Substrate isolation structures 225 may be formed adjacent to and around a lower portion of active region 222 (e.g., protrusion 205L′ thereof), and active region 222 may be separated and/or electrically isolated from other active regions by substrate isolation structures 225. Substrate isolation structures 225 include silicon oxide, silicon nitride, silicon oxynitride, other suitable isolation material (including, silicon, oxygen, nitrogen, carbon, other suitable isolation constituent, or combinations thereof), or combinations thereof. Substrate isolation structures 225 may have a multilayer structure. For example, substrate isolation structures 225 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 225 may include a bulk dielectric over a doped liner, such as a boron silicate glass (BSG) liner and/or a phosphosilicate glass (PSG) liner. Dimensions and/or characteristics of substrate isolation structures 225 may be configured to provide shallow trench isolation (STI) structures, deep trench isolation (DTI) structures, local oxidation of silicon (LOCOS) structures, other suitable isolation structures, or combinations thereof.

Referring to FIG. 2B and FIG. 3F, method 100B at block 115 includes forming a gate structure (e.g., gate structures 230) over a first region (e.g., channel regions) of the active region (e.g., active region 222) of the stacked device structure (e.g., stacked device structure 200). Gate structures 230 extend lengthwise along a direction different than (e.g., orthogonal to) the lengthwise direction of active region 222. For example, gate structures 230 may extend along the y-direction, having a length along the y-direction, a width along the x-direction, and a height along the z-direction. Along a gate lengthwise direction, gate structures 230 may extend substantially parallel to one another. Along a gate widthwise direction (FIG. 3F), gate structures 230 may be disposed between respective source/drain regions of active region 222.

Each gate structure 230 may include a respective dummy gate 232 and respective gate spacers 234. Along the gate lengthwise direction (e.g., in a Y-Z cross-sectional view), dummy gates 232 are disposed over a top and sidewalls of active region 222, and dummy gates 232 may wrap active region 222. Along a gate widthwise direction (FIG. 3F), dummy gates 232 are disposed on a top of active region 222, and gate spacers 234 are disposed adjacent to and along sidewalls of a respective dummy gate 232. Dummy gates 232 may each include a respective dummy gate dielectric 236 (e.g., a silicon oxide layer), a respective dummy gate electrode 238 (e.g., a polysilicon layer), and other layers (e.g., a respective hard mask 239). In some embodiments, forming dummy gates 232 includes depositing a dummy gate dielectric layer over active region 222, depositing a dummy gate electrode layer over the dummy gate dielectric layer, depositing a hard mask layer over the dummy gate electrode layer, and performing one or more lithography and etching processes to pattern the hard mask layer, the dummy gate electrode layer, and the dummy gate dielectric layer. Remainders of the hard mask layer, the dummy gate electrode layer, and the dummy gate dielectric layer may form dummy gate dielectrics 236, dummy gate electrodes 238, and hard masks 239, respectively, of dummy gates 232.

Gate spacers 234 (44) are formed adjacent to and along sidewalls of dummy gates 232. In some embodiments, fin spacers are formed adjacent to and along sidewalls of active region 222 in source/drain regions thereof. Gate spacers 234 and the fin spacers include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, gate spacers 234 and/or the fin spacers have a multilayer structure, such as two or more dielectric layers having different compositions. In some embodiments, gate spacers 234 and/or the fin spacers include more than one set of spacers, such as seal spacers, offset spacers, sacrificial spacers, dummy spacers, main spacers, or combinations thereof. In such embodiments, the various sets of spacers may have different compositions. Gate spacers 234 and/or the fin spacers may be formed by any suitable process, and in some embodiments, gate spacers 234 and the fin spacers are formed simultaneously.

Referring to FIG. 2B and FIGS. 3G-3O, method 100B at block 120 includes forming a source/drain stack in a second region (e.g., source/drain regions) of the active region (e.g., active region 222) of the stacked device structure (e.g., stacked device structure 200). The source/drain stack includes a lower source/drain (e.g., source/drains 260L), an upper source/drain (e.g., source/drains 260U), and a source/drain isolation structure (e.g., source/drain isolation structures 265, which correspond with isolation structures 18) between the lower source/drain and the upper source/drain. As described below, the source/drain stack may be fabricated with a self-aligned two-step source/drain etch that does not implement dummy source/drains (i.e., temporary source/drain placeholders), which may improve device uniformity (e.g., by reducing differences in heights/thicknesses of lower source/drains, reducing heights/thicknesses heights of upper source/drains, reducing variations in source/drain sidewall profiles, etc.).

Referring to FIG. 2B and FIG. 3G, method 100B at block 125 includes forming a first portion of a source/drain trench (e.g., source/drain trenches 240) in a first multilayer stack (e.g., multilayer stack 210U) of the second region (e.g., source/drain regions) of the active region (e.g., active region 222) of the stacked device structure (e.g., stacked device structure 200). In some embodiments, a source/drain etch removes portions of multilayer stack 210U that are not covered by gate structures 230 to form source/drain trenches (recesses) 240. For example, the source/drain etch may remove semiconductor layers 220U and sacrificial layers 215U in the source/drain regions, but not the channel regions, of active region 222, thereby exposing bonding/insulation structure 218 therein. Accordingly, source/drain trenches 240 may have bottoms formed by bonding/insulation structure 218 (e.g., bonding/insulation layer 218U thereof) and sidewalls formed by portions of multilayer stack 210U that remain in the channel regions (e.g., remainders of semiconductor layers 220U and sacrificial layers 215U thereof). In the depicted embodiment, source/drain trenches 240 have a depth d1 and a width w1. Depth d1 is between a top of active region 222 and top of bonding/insulation structure 218 (which provides bottoms of source/drain trenches 240). In some embodiments, depth d1 is equal to a thickness of multilayer stack 210U. The source/drain etch is a dry etch, a wet etch, other suitable etch, or combinations thereof. In some embodiments, the source/drain etch is a multistep etch process, which may alternate etchants to remove sacrificial layers 215U and semiconductor layers 220U separately and alternately. In some embodiments, source/drain etch parameters (e.g., etchant thereof) are tuned to selectively remove semiconductor materials (e.g., semiconductor layers 220U and sacrificial layers 215U) without (or negligibly) removing dielectric materials (e.g., bonding/insulation structure 218, dummy gates 232 (e.g., hard masks 239 thereof), gate spacers 234, substrate isolation structures 225, etc.). Because the source/drain etch may selectively remove exposed portions of multilayer stack 210U relative to bonding/insulation structure 218, source/drain trenches 240 have depth uniformity (i.e., source/drain trenches 240 have the same depth (e.g., depth d1)).

Referring to FIG. 3H, in some embodiments, inner spacers 244U of upper device(s) (e.g., device 14U and/or transistors 20U) of stacked device structure 200 may be formed after forming source/drain trenches 240 in multilayer stack 210U. For example, inner spacers 244U are formed under gate spacers 234 along sidewalls of sacrificial layers 215U. Inner spacers 244U may replace edges/ends of sacrificial layers 215U, such as portions disposed under gate spacers 234. Accordingly, after forming inner spacers 244U, sidewalls of source/drain trenches 240 may be formed by semiconductor layers 220U (i.e., portions remaining in the channel regions of active region 222) and inner spacers 244U, instead of sacrificial layers 215U. In the depicted embodiment, top inner spacers 244U are disposed between ends of respective semiconductor layers 220U, bottom inner spacers 244U are disposed between ends of bottom semiconductor layers 220U and bonding/insulation structure 218, and remainders of sacrificial layers 215U are disposed between respective inner spacers 244U.

Forming inner spacers 244U may include a first inner spacer etch, an inner spacer deposition, and a second inner spacer etch. The first inner spacer etch may selectively etch sacrificial layers 215U without (or negligibly) etching semiconductor layers 220U, bonding/insulation structure 218, dummy gates 232 (e.g., hard masks 239 thereof), gate spacers 234, substrate isolation structures 225, or combinations thereof. The first inner spacer etch may be configured to laterally etch sacrificial layers 215U to reduce their lengths along the x-direction, such that lengths of sacrificial layers 215U are less than lengths of semiconductor layers 220U. The first inner spacer etch may form upper notches between semiconductor layers 220U and between bottom semiconductor layer 220U and bonding/insulation structure 218. In some embodiments, the upper notches laterally extend (e.g., along the x-direction) under dummy gates 232. The first inner spacer etch is a dry etch, a wet etch, or combinations thereof.

The inner spacer deposition forms an inner spacer layer over stacked device structure 200 that at least partially fills the upper notches. In some embodiments, a single deposition process is performed to form an inner spacer layer that at least partially fills the upper notches. In some embodiments, inner spacers 244U have multilayer structures, and the inner spacer deposition includes more than one deposition process to form a multilayer inner spacer layer, such as a first deposition process to form a first inner spacer sublayer and a second deposition process to form a second inner spacer sublayer. The first inner spacer sublayer partially fills the upper notches, and the second inner spacer sublayer may partially or completely fill the upper notches. In some embodiments, a composition of the first inner spacer sublayer is the same as a composition of the second inner spacer sublayer. In some embodiments, the first inner spacer sublayer and the second inner spacer sublayer have different compositions.

The second inner spacer etch may selectively etch the inner spacer layer without (or negligibly) etching semiconductor layers 220U, bonding/insulation structure 218, dummy gates 232 (e.g., hard masks 239 thereof), gate spacers 234, substrate isolation structures 225, or combinations thereof. Remainders of the inner spacer layer provide inner spacers 244U, such as depicted. To achieve desired etching selectivity, the inner spacer layer (and thus inner spacers 244U) has a composition different than compositions of semiconductor layers 220U, bonding/insulation structure 218, dummy gates 232 (e.g., hard masks 239 thereof), gate spacers 234, substrate isolation structures 225, or combinations thereof. In some embodiments, the inner spacer layer includes a dielectric material that includes silicon, oxygen, carbon, nitrogen, other suitable dielectric constituent, or combinations thereof. For example, the inner spacer layer may be a silicon carbide layer, a silicon carbonitride layer, a silicon oxycarbonitride layer, a silicon oxycarbide layer, or combinations thereof. The second inner spacer etching process is a dry etch, a wet etch, or combinations thereof. In some embodiments, the inner spacer deposition and/or the second inner spacer etch are tuned to provide inner spacers 244U with air gaps.

Referring to FIG. 2B and FIG. 3I, method 100B at block 130 includes forming dummy sidewall masks (e.g., dummy sidewall masks 250) in the source/drain trench (e.g., source/drain trenches 240). Dummy sidewall masks 250 are disposed on and completely cover sidewalls of source/drain trenches 240 (e.g., provided by semiconductor layers 220U and inner spacers 244U), but not bottoms of source/drain trenches 240 (e.g., provided by bonding/insulation structure 218). Because source/drain trenches 240 have depth uniformity (i.e., source/drain trenches 240 have the same depth (e.g., depth d1)), bottoms of dummy sidewall masks 250 are at a same depth (e.g., depth d1) in source/drain regions of active region 222. Dummy sidewall masks 250 have a thickness t (e.g., along the x-direction) and a height (e.g., along the z-direction), and dummy sidewall masks 250 partially fill source/drain trenches 240, thereby reducing width w1 of source/drain trenches 240 to a width w2. In some embodiments, thickness t is about 1 nm to about 10 nm. In some embodiments, thickness t is less than half of width w1 (i.e., t<0.5*w1) to ensure that dummy sidewall masks 250 do not completely fill source/drain trenches 240. In some embodiments, the height of dummy sidewall masks 250 is greater than or equal to depth d1 to ensure coverage of sidewalls of source/drain trenches 240 (in which upper source/drains are subsequently formed). In some embodiments, such as depicted, dummy sidewall masks 250 are further disposed on gate spacers 234 (e.g., sidewalls thereof), such that dummy sidewall masks 250 extend from tops of gate spacers 234 to the top of bonding/insulation structure 218. In such embodiments, a height of dummy sidewall masks 250 (e.g., along the z-direction) may be equal to a sum of a height of gate spacers 234 (e.g., along the z-direction) and depth d1 of source/drain trenches 240.

A composition of dummy sidewall masks 250 is different than a composition of multilayer stack 210L (e.g., sacrificial layers 215L and semiconductor layers 220L), a composition of bonding/insulation structure 218, a composition of semiconductor layers 220U, a composition of inner spacers 244U (e.g., a portion thereof abutted by dummy sidewall masks 250), a composition of gate spacers 234 (e.g., a portion thereof abutted by dummy sidewall masks 250), a composition of dummy gates 232 (e.g., hard masks 239 thereof), subsequently formed source/drains, or combinations thereof. Dummy sidewall masks 250 are formed of a dielectric material or other suitable material that achieves etch selectivity as described herein, and dummy sidewall masks 250 are formed by any suitable process. In some embodiments, dummy sidewall masks 250 include silicon and nitrogen (e.g., silicon nitride). In some embodiments, dummy sidewall masks 250 include metal and oxygen (e.g., metal oxide). In some embodiments, dummy sidewall masks 250 are formed by performing a dummy material deposition and a dummy material etch. The dummy material deposition may form a dummy material layer over stacked device structure 200, such as over top of bonding/insulation structure 218, tops of gate structures 230 (e.g., tops of dummy gates 232 (e.g., hard masks 239 thereof) and tops of gate spacers 234 thereof), sides of gate structures 230 (e.g., over sidewalls of gate spacers 234 thereof), and sidewalls of source/drain trenches 240. The dummy material etch may remove the dummy material layer from horizontally oriented surfaces, but not vertically oriented surfaces, of stacked device structure 200. For example, the dummy material etch may remove portions of the dummy material layer over top of bonding/insulation structure 218, tops of dummy gates 232 (e.g., hard masks 239 thereof), and tops of gate spacers 234, such that remainders of the dummy material layer over sidewalls of gate spacers 234 and sidewalls of source/drain trenches 240 provide dummy sidewall masks 250. In some embodiments, the dummy material etch is an anisotropic etch process, which generally refers to an etch process having different etch rates in different directions, such that the etch process removes material in specific directions, such as substantially in one direction. For example, the dummy material etch may have a vertical etch rate that is greater than a horizontal etch rate (in some embodiments, the horizontal etch rate is zero), such that the dummy material etch removes material in substantially the vertical direction (e.g., z-direction) with minimal (to no) material removal in the horizonal direction (e.g., x-direction and/or y-direction). In such embodiments, the dummy material etch does not remove, or negligently removes, portions of the dummy material layer covering sidewalls of source/drain trenches 240 and sidewalls of gate spacers 234.

Referring to FIG. 2B and FIG. 3J, method 100B at block 135 includes extending the source/drain trench (e.g., source/drain trenches 240) into the bonding/insulation structure (e.g., bonding/insulation structure 218) and a second multilayer stack (e.g., multilayer stack 210L), such that a second portion of the source/drain trench is in the bonding/insulation structure and a third portion of the source/drain trench is in the second multilayer stack. In some embodiments, a source/drain etch removes portions of multilayer stack 210L that are not covered by gate structures 230 to extend source/drain trenches 240. For example, the source/drain etch may remove bonding/insulation structure 218, semiconductor layers 220L, and sacrificial layers 215L in the source/drain regions, but not the channel regions, of active region 222. The source/drain etch may further remove substrate 205L in the source/drain regions, but not the channel regions, of active region 222. Accordingly, source/drain trenches 240 may have bottoms formed by substrate 205 and sidewalls further formed by portions of substrate 205L (e.g., protrusion 205L′ thereof), portions of bonding/insulation structure 218 (which correspond with isolation structures 17 of stacked device structure 10), and portions of multilayer stack 210L that remain in the channel regions (e.g., remainders of semiconductor layers 220L and sacrificial layers 215L thereof). In the depicted embodiment, source/drain trenches 240 have a depth d2, width w2 (which corresponds with spacing between dummy sidewall masks 250 formed therein), and a width w3 in bonding/insulation structure 218, multilayer stack 210L, and substrate 205. Depth d2 is between a top of active region 222 and substrate 205L (e.g., protrusion 205L′ thereof, which provides bottoms of source/drain trenches 240), and depth d2 is greater than depth d1. In some embodiments, depth d2 is greater than or equal to a sum of a thickness of multilayer stack 210U, a thickness of bonding/insulation structure 218, and a thickness of multilayer stack 210L. In some embodiments, width w3 is equal to width w2. In other words, spacing (e.g., width w2) between dummy sidewall masks 250 formed in the portion of source/drain trenches 240 in multilayer stack 210U may define widths (e.g., width w3) of the portions of source/drain trenches 240 in bonding/insulation structure 218 and multilayer stack 210L. In some embodiments, the source/drain fabrication process provides source/drain trenches 240 with depth uniformity (i.e., source/drain trenches 240 have the same depth (e.g., depth d2)).

The source/drain etch is a dry etch, a wet etch, other suitable etch, or combinations thereof. In some embodiments, the source/drain etch is a multistep etch process. For example, the source/drain etch may include a first etch that selectively removes bonding/insulation structure 218 and a second etch that selectively removes multilayer stack 210L. In some embodiments, first source/drain etch parameters (e.g., etchant thereof) are tuned to selectively remove bonding/insulation structure 218 (e.g., dielectric material) without (or negligibly) removing dummy sidewall masks 250 (e.g., silicon nitride or metal oxide), gate spacers 234, dummy gates 232 (e.g., hard masks 239 thereof), multilayer stack 210L (e.g., top sacrificial layer 215L thereof), or combinations thereof. In some embodiments, second source/drain etch parameters (e.g., etchant thereof) are tuned to selectively remove multilayer stack 210L (e.g., semiconductor materials) without (or negligibly) removing dummy sidewall masks 250 (e.g., silicon nitride or metal oxide), bonding/insulation structure 218 (e.g., dielectric material), gate spacers 234, dummy gates 232, or combinations thereof. The second etch may alternate etchants to remove sacrificial layers 215L and semiconductor layers 220U separately and alternately. Because the source/drain etch for forming lower portions of source/drain trenches 240 (e.g., in multilayer stack 210L) may utilize dummy sidewall masks 250 as etch masks, lower, bottom source/drain etch may be referred to as a self-aligned source/drain etch. In other words, lower, bottom source/drain recesses may be formed without forming a patterned mask layer (e.g., using a lithography process and an etching process) over stacked device structure 200.

Referring to FIG. 3K, in some embodiments, inner spacers 244L of lower device(s) (e.g., device 14L and/or transistors 20L) of stacked device structure 200 may be formed after extending source/drain trenches 240 into multilayer stack 210L. For example, inner spacers 244L are formed under gate spacers 234 along sidewalls of sacrificial layers 215L. Inner spacers 244L and inner spacers 244U may collectively be referred to inner spacers 244 (inner spacers 54, such as depicted in FIGS. 1A-1C). Inner spacers 244L may replace edges/ends of sacrificial layers 215L, such as portions disposed under gate spacers 234. In the depicted embodiment, top inner spacers 244L are disposed between bonding/insulation structure 218 and ends of top semiconductor layers 220L, middle inner spacers 244L are disposed between ends of semiconductor layers 220L, bottom inner spacers 244L are disposed between ends of bottom semiconductor layers 220L and protrusion 205L′, and remainders of sacrificial layers 215L are disposed between respective inner spacers 244L. In some embodiments, a configuration (e.g., number of inner layers, types of material(s), whether configured with or without air gaps, etc.) and/or a composition of inner spacers 244L is the same as a configuration and/or a composition of inner spacers 244U. In some embodiments, a configuration and/or a composition of inner spacers 244L is different than a configuration and/or a composition of inner spacers 244U.

Forming inner spacers 244L may include a first inner spacer etch, an inner spacer deposition, and a second inner spacer etch. The first inner spacer etch may selectively etch sacrificial layers 215L without (or negligibly) etching dummy sidewall masks 250, semiconductor layers 220L, protrusion 205L′, bonding/insulation structure 218, dummy gates 232 (e.g., hard masks 239 thereof), gate spacers 234, substrate isolation structures 225, or combinations thereof. The first inner spacer etch may be configured to laterally etch sacrificial layers 215L to reduce their lengths along the x-direction, such that lengths of sacrificial layers 215L are less than lengths of semiconductor layers 220L. The first inner spacer etch may form lower notches between semiconductor layers 220L, between top semiconductor layers 220L and bonding/insulation structure 218, and between bottom semiconductor layers 220L and protrusion 205L′. In some embodiments, the lower notches laterally extend under dummy gates 232. The first inner spacer etch is a dry etch, a wet etch, or combinations thereof.

The inner spacer deposition forms an inner spacer layer over stacked device structure 200 that at least partially fills the lower notches. In some embodiments, a single deposition process is performed to form an inner spacer layer that at least partially fills the lower notches. In some embodiments, inner spacers 244L have multilayer structures, and the inner spacer deposition includes more than one deposition process to form a multilayer inner spacer layer, such as a first deposition process to form a first inner spacer sublayer and a second deposition process to form a second inner spacer sublayer. The first inner spacer sublayer partially fills the lower notches, and the second inner spacer sublayer may partially or completely fill the lower notches. In some embodiments, a composition of the first inner spacer sublayer is the same as a composition of the second inner spacer sublayer. In some embodiments, the first inner spacer sublayer and the second inner spacer sublayer have different compositions.

The second inner spacer etch may selectively etch the inner spacer layer without (or negligibly) etching dummy sidewall masks 250, semiconductor layers 220L, protrusion 205L′ (and/or substrate 205), bonding/insulation structure 218, dummy gates 232, gate spacers 234, substrate isolation structures 225, or combinations thereof. Remainders of the inner spacer layer provide inner spacers 244L, such as depicted. To achieve desired etching selectivity, the inner spacer layer (and thus inner spacers 244L) has a composition different than compositions of dummy sidewall masks 250, semiconductor layers 220L, bonding/insulation structure 218, dummy gates 232 (e.g., hard masks 239 thereof), gate spacers 234, substrate isolation structures 225, or combinations thereof. In some embodiments, the inner spacer layer includes a dielectric material that includes silicon, oxygen, carbon, nitrogen, other suitable dielectric constituent, or combinations thereof. For example, the inner spacer layer may be a silicon carbide layer, a silicon carbonitride layer, a silicon oxycarbonitride layer, a silicon oxycarbide layer, or combinations thereof. The second inner spacer etch is a dry etch, a wet etch, or combinations thereof. In some embodiments, parameters of the inner spacer deposition and/or the second inner spacer etch are tuned to provide inner spacers 244L with air gaps.

Referring to FIG. 2B and FIG. 3L, method 100B at block 140 includes forming a first source/drain (e.g., source/drains 260L) in the third portion of the source/drain trench (e.g., portions of source/drain trenches 240 in multilayer stack 210L). Source/drains 260L partially fill source/drain trenches 240 (e.g., lower portions thereof). Source/drains 260L are disposed between and adjacent to semiconductor layers 220L remaining in channel regions (e.g., providing channels of lower devices (e.g., device 14L and/or transistors 20L)), and source/drains 260L provide source/drains of lower devices (e.g., device 14L and/or transistors 20L). Source/drains 260L have a width w4 and a height h1. In some embodiments, width w4 is equal to width w3 (which may be equal to width w2). Height h1 (e.g., along the z-direction) is between tops of source/drains 260L and bottoms of source/drains 260L, and height h1 is less than a sum of a thickness of bonding/insulation structure 218 and a thickness of multilayer stack 210L. In the depicted embodiment, height h1 is equal to a thickness of multilayer stack 210L. Because source/drain trenches 240 have depth uniformity (i.e., source/drain trenches 240 have the same depth (e.g., depth d2)) and source/drains 260L may be formed by a selective deposition process (i.e., one that selectively deposits/grows semiconductor material on semiconductor surfaces, but not dielectric surfaces) as described herein, source/drains 260L may have height uniformity (i.e., source/drains 260L have the same height (e.g., height h1)).

In the depicted embodiment, lower transistors of stacked device structure 200 are p-type transistors, and source/drains 260L are configured for p-type transistors. For example, source/drains 260L includes silicon germanium or germanium doped with boron, other p-type dopant, or combinations thereof. In such example, source/drains 260L may be Si:Ge:B epitaxial source/drains. In some embodiments, the lower transistors of stacked device structure 200 are n-type transistors, and source/drains 260L are configured for n-type transistors. For example, source/drains 260L include silicon doped with carbon, phosphorous, arsenic, other n-type dopant, or combinations thereof. In such example, source/drains 260L may be Si:C epitaxial source/drains, Si:P epitaxial source/drains, or Si:C:P epitaxial source/drains. Source/drains 260L may have a multilayer structure. In some embodiments, source/drains 260L include semiconductor layers having different compositions, and the different compositions may be achieved by configuring the semiconductor layers with different semiconductor materials, different dopants, different atomic percentages of constituents thereof, different dopant concentrations, or combinations thereof. For example, one or more of source/drains 260L may include an undoped semiconductor layer disposed in substrate 205 (e.g., protrusion 205L′ thereof) and a doped semiconductor layer disposed over the undoped semiconductor layer. The undoped semiconductor layer is disposed below bottom semiconductor layers 220L, and the doped semiconductor layer is disposed adjacent to semiconductor layers 220L. The doped semiconductor layer may have a multilayer structure, such as an inner doped semiconductor layer and an outer doped semiconductor layer. The outer doped semiconductor layer (which may be formed of discrete segments, in some embodiments) is disposed between semiconductor layers 220L and the inner doped semiconductor layer. In some embodiments, the outer doped semiconductor layer is disposed between inner spacers 244L and the inner doped semiconductor layer and/or between the undoped semiconductor layer and the inner doped semiconductor layer. In some embodiments, source/drains 260L include an insulator layer (e.g., a dielectric layer) disposed between the undoped semiconductor layer and the doped semiconductor layer, and the insulator layer is disposed below bottom semiconductor layers 220L.

Source/drains 260L may be formed by an epitaxy process. The epitaxy process may include epitaxially growing semiconductor material from exposed semiconductor surfaces, such as semiconductor layers 220L and/or substrate 205 (e.g., protrusion 205L′ thereof), that fills the portions of source/drain trenches 240 in multilayer stack 210L. The epitaxy process may use CVD deposition techniques (e.g., remote plasma CVD (RPCVD), low pressure CVD (LPCVD), vapor phase epitaxy (VPE), ultrahigh vacuum CVD (UHV-CVD), or combinations thereof), MBE, other epitaxy process, or combinations thereof. The epitaxy process may use gaseous precursors and/or liquid precursors, which may interact with and/or adsorb semiconductor layers 220L and/or substrate 205, but not interact with dummy sidewall masks 250, bonding/insulation structure 218, inner spacers 244L, hard masks 239, gate spacers 234, or combinations thereof. In some embodiments, source/drains 260L are doped during deposition (i.e., in-situ), for example, by adding dopant to a source material of the epitaxy process. In some embodiments, source/drains 260L are doped after deposition thereof, for example, by an ion implantation process. In some embodiments, annealing processes (e.g., rapid thermal annealing and/or laser annealing) are performed to activate dopants in source/drains 260L. In some embodiments, source/drains 260L includes materials and/or dopants that achieve desired tensile stress and/or compressive stress in channel regions (e.g., semiconductor layers 220L). In some embodiments, doped regions, such as heavily doped source/drain (HDD) regions, lightly doped source/drain (LDD) regions, other doped regions, or combinations thereof, are disposed in source/drains 260L. As used herein, source/drain region, source/drain (e.g., source/drain 260L and/or source/drain 260U described herein), epitaxial source/drain, epitaxial source/drain feature, etc. may refer to a source of a device (e.g., a transistor), a drain of a device (e.g., a transistor), or a source and/or a drain of multiple devices (e.g., multiple transistors).

Referring to FIG. 2B and FIG. 3M, method 100B at block 145 includes removing the dummy sidewall masks (e.g., dummy sidewall masks 250) in the source/drain trench (e.g., source/drain trenches 240). For example, an etching process may remove dummy sidewall masks 250 from source/drain trenches 240. The etching process may selectively etch dummy sidewall masks 250 without (or negligibly) etching source/drains 260L, semiconductor layers 220U, bonding/insulation structure 218, dummy gates 232 (e.g., hard masks 239 thereof), gate spacers 234, substrate isolation structures 225, or combinations thereof. The etching process is a dry etch, a wet etch, other suitable etch, or combinations thereof. In some embodiments, etch parameters (e.g., etchant thereof) are tuned to selectively remove silicon nitride or metal oxide (e.g., dummy sidewall masks 250) without (or negligibly) removing semiconductor materials (e.g., semiconductor layers 220U and source/drains 260L) and other dielectric materials (e.g., bonding/insulation structure 218, dummy gates 232 (e.g., hard masks 239 thereof), gate spacers 234, the fin spacers, substrate isolation structures 225, etc.). In some embodiments, the etching process may be a wet etch that exposes stacked device structure 200 to a wet etchant. For example, stacked device structure 200 may be exposed to and/or immersed in hot phosphoric acid (e.g., H₃PO₄) to remove dummy mask sidewalls 250 (e.g., silicon nitride).

After removing dummy sidewall masks 250, source/drain trenches 240 have a depth d3, an upper portion (e.g., in multilayer stack 210U) having width w1, and a lower portion having width w3 (e.g., in bonding/insulation structure 218). Source/drain trenches 240 thus have a width that varies along depth d3. For example, width w1 is greater than width w3 (which corresponds with spacing between dummy sidewall masks 250). Depth d3 is between a top of active region 222 (e.g., tops of semiconductor layers 220U) and tops of source/drains 260L (which provides bottoms of remaining source/drain trenches 240). Depth d3 is less than depth d2 and greater than depth d1. In some embodiments, depth d3 is equal to a sum of a thickness of multilayer stack 210U and a thickness of bonding/insulation structure 218.

Referring to FIG. 2B and FIG. 3N, method 100B at block 150 includes forming a source/drain insulation structure (e.g., source/drain isolation structures 265 (which correspond with isolation structures 18)) in the second portion of the source/drain trench (e.g., portions of source/drain trenches 240 in bonding/insulation structure 218). Source/drain isolation structures 265 partially fill source/drain trenches 240 (e.g., middle portions thereof). Source/drain isolation structures 265 are disposed between and adjacent to portions of bonding/insulation structure 218 remaining in channel regions (e.g., providing channel isolation structures (e.g., isolation structures 17)). Source/drain isolation structures 265 have a width w5 and a height h2. In some embodiments, width w5 is equal to width w3 (which may be equal to width w4 and/or width w2). Height h2 (e.g., along the z-direction) is between tops of source/drain isolation structures 265 and bottoms of source/drain isolation structures 265, and height h2 is less than or equal to a thickness of bonding/insulation structure 218. In the depicted embodiment, height h2 is equal to a thickness of bonding/insulation structure 218. Accordingly, tops of source/drain isolation structures 265 and tops of bonding/insulation structure 218 (i.e., channel isolation structures) may be at a same height above substrate 205L, and bottoms of source/drain isolation structures 265 and bottoms of bonding/insulation structure 218 (i.e., channel isolation structures) may be at a same height above substrate 205L. In other words, tops of source/drain isolation structures 265 and tops of bonding/insulation structure 218 (i.e., channel isolation structures) are substantially coplanar, and bottoms of source/drain isolation structures 265 and bottoms of bonding/insulation structure 218 (i.e., channel isolation structures) are substantially coplanar.

Source/drain isolation structures 265 may have a multilayer structure, such as a CESL 270L (which corresponds with CESL 70L) and an ILD layer 272L (which corresponds with ILD layer 70L). ILD layer 272L includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or combinations thereof. In some embodiments, ILD layer 272L include a dielectric material having a dielectric constant that is less than a dielectric constant of silicon dioxide (e.g., k<3.9). In some embodiments, ILD layer 272L includes a dielectric material having a dielectric constant that is less than about 2.5 (i.e., an extreme low-k (ELK) dielectric material), such as porous silicon oxide, silicon carbide, carbon-doped oxide (e.g., an SiCOH-based material (having, for example, Si-CH₃ bonds)), or combinations thereof, each of which is tuned/configured to have a dielectric constant less than about 2.5. CESL 270L include a dielectric material that is different than the dielectric material of ILD layer 272L. For example, where ILD layer 272L include a low-k dielectric material (e.g., porous silicon oxide), CESL 270L may include silicon and nitrogen and/or carbon, such as silicon nitride, silicon carbonitride, or silicon oxycarbonitride. In some embodiments, CESL 270L may include metal and oxygen, nitrogen, carbon, or combinations thereof. In some embodiments, CESL 270L includes silicon and oxygen, such as silicon oxide. In some embodiments, ILD layer 272L is formed of PSG, BSG, BPSG, or undoped silicate glass (USG), and CESL 270L is formed of silicon nitride, silicon oxynitride, or silicon oxide. In some embodiments, ILD layer 272L and/or CESL 270L has a multilayer structure.

In some embodiments, forming source/drain isolation structures 265 includes depositing a first dielectric layer having a first thickness (e.g., a CESL) over source/drains 260L, depositing a second dielectric layer having a second thickness (e.g., an ILD layer) over the first dielectric layer, and etching back the first dielectric layer and the second dielectric layer below bottom semiconductor layer 220U. The first thickness is less than the second thickness; the first thickness is configured to provide the first dielectric layer partially filling at least middle portions of source/drain trenches 240 (e.g., portions in bonding/insulation structure 218 having width w3); and the second thickness is configured to provide the second dielectric layer filling remainders of at least the middle portions of source/drain trenches 240 (e.g., portions in bonding/insulation structure 18 having width w3). In some embodiments, the first dielectric layer partially fills the upper portions of source/drain trenches 240 (e.g., portions in multilayer stack 210U), and the second dielectric layer fills remainders of the upper portions of source/drain trenches 240. In some embodiments, the etching back removes the first dielectric layer and the second dielectric layer from the upper portions of source/drain trenches 240. In some embodiments, the etching back provides source/drain isolation structures 265 (e.g., the first dielectric layer and the second dielectric layer) with a height that is about the same as (e.g., equal to) a thickness of bonding/insulation structure 218. The first dielectric layer and the second dielectric layer are formed by CVD and/or other suitable method. The first dielectric layer and the second dielectric layer (and thus CESL 270L and ILD layer 272L, respectively) may be formed inside source/drain trenches 240 and outside source/drain trenches 240, such that CESL 270L and ILD layer 272L are formed over/on substrate isolation structures 225. In some embodiments, ILD layer 272L is formed by flowable CVD (FCVD), high aspect ratio (HARP) deposition, high density plasma CVD (HDPCVD), or combinations thereof.

Referring to FIG. 2B and FIG. 3O, method 100B at block 155 includes forming a second source/drain (e.g., source/drains 260U) in the first portion of the source/drain trench (e.g., portions of source/drain trenches 240 in multilayer stack 210U). Source/drains 260U fill remainders of source/drain trenches 240 (e.g., upper portions thereof). Source/drains 260U are disposed between and adjacent to semiconductor layers 220U remaining in channel regions (e.g., providing channels of upper devices (e.g., device 14U and/or transistors 20U)), source/drains 260U are disposed over source/drain isolation structures 265, and source/drains 260U provide source/drains of upper devices (e.g., device 14U and/or transistors 20U). Source/drains 260U have a width w6 and a height h3. In some embodiments, width w6 is equal to width w1, and width w6 is greater than width w4 (of source/drains 260L) and width w5 (of source/drain isolation structures 265). Height h3 (e.g., along the z-direction) is between tops of source/drains 260U and bottoms of source/drains 260U, and height h3 is greater than or equal to a thickness of multilayer stack 210U. In the depicted embodiment, height h3 is greater than a thickness of multilayer stack 210U. In some embodiments, source/drains 260U have height uniformity (i.e., source/drains 260U have the same height (e.g., height h1)).

In the depicted embodiment, upper transistors of stacked device structure 200 are n-type transistors, and source/drains 260U are configured for n-type transistors. For example, source/drains 260U include silicon doped with carbon, phosphorous, arsenic, other n-type dopant, or combinations thereof. In such example, source/drains 260U may be Si:C epitaxial source/drains, Si:P epitaxial source/drains, or Si:C:P epitaxial source/drains. In some embodiments, the upper transistors of stacked device structure 200 are p-type transistors, and source/drains 260U are configured for p-type transistors. For example, source/drains 260U include silicon germanium or germanium doped with boron, other p-type dopant, or combinations thereof. In such example, source/drains 260U may be Si:Ge:B epitaxial source/drains. Source/drains 260U may have a multilayer structure. In some embodiments, source/drains 260U include semiconductor layers having different compositions, and the different compositions may be achieved by configuring the semiconductor layers with different semiconductor materials, different dopants, different atomic percentages of constituents thereof, different dopant concentrations, or combinations thereof. For example, one or more of source/drains 260U may include a doped semiconductor layer having a multilayer structure, such as an inner doped semiconductor layer and an outer doped semiconductor layer. The outer doped semiconductor layer (which may be formed of discrete segments, in some embodiments) is disposed between semiconductor layers 220U and the inner doped semiconductor layer. In some embodiments, the outer doped semiconductor layer is disposed between inner spacers 244U and the inner doped semiconductor layer and/or between source/drain isolation structures 265 and the inner doped semiconductor layer. In some embodiments, source/drains 260L may include an undoped semiconductor layer disposed between the doped semiconductor layer and source/drain isolation structures 265, and the undoped semiconductor layer may be disposed below bottom semiconductor layers 220U. In some embodiments, source/drains 260U include an insulator layer disposed between the undoped semiconductor layer and the doped semiconductor layer, and the insulator layer is disposed below bottom semiconductor layers 220U.

Source/drains 260U may be formed by an epitaxy process. The epitaxy process may include epitaxially growing semiconductor material from exposed semiconductor surfaces, such as semiconductor layers 220U, that fills the portions of source/drain trenches 240 in multilayer stack 210U. The epitaxy process may use CVD deposition techniques (e.g., RPCVD, LPCVD, VPE, UHV-CVD, or combinations thereof), MBE, other epitaxy process, or combinations thereof. The epitaxy process may use gaseous precursors and/or liquid precursors, which may interact with and/or adsorb on semiconductor layers 220U, but not interact with source/drain isolation structures 265 (e.g., CESL 270L and/or ILD layer 272L thereof), inner spacers 244U, dummy gates 232 (e.g., hard masks 239 thereof), gate spacers 234, or combinations thereof. In some embodiments, source/drains 260U are doped during deposition (i.e., in-situ), for example, by adding dopant to a source material of the epitaxy process. In some embodiments, source/drains 260U are doped after deposition thereof, for example, by an ion implantation process. In some embodiments, annealing processes (e.g., rapid thermal annealing and/or laser annealing) are performed to activate dopants in source/drains 260U. In some embodiments, source/drains 260U includes materials and/or dopants that achieve desired tensile stress and/or compressive stress in channel regions (e.g., semiconductor layers 220U). In some embodiments, doped regions, such as HDD regions, LDD regions, other doped regions, or combinations thereof, are disposed in source/drains 260U.

Referring to FIG. 3P, in some embodiments, an insulation structure 268 is formed over source/drains 260U. Insulation structure 268 may fill spaces between gate structures 230 (e.g., gate spacers 234 thereof), and portions of insulation structure 268 between gate structures 230 may have a width w7, which is greater than width w5 (of source/drain isolation structures 265). In some embodiments, width w1 is equal to width w6 (or source/drains 260U). Insulation structure 268 may have a multilayer structure, such as a CESL 270U (which corresponds with CESL 70U) and an ILD layer 272U (which corresponds with ILD layer 70U). ILD layer 272U may be similar to ILD layer 272L, and CESL 270U may be similar to CESL 270L. For example, ILD layer 272U includes a dielectric material including, for example, silicon oxide, carbon doped silicon oxide, silicon nitride, silicon oxynitride, TEOS-formed oxide, BSG, PSG, BPSG, FSG, xerogel, aerogel, amorphous fluorinated carbon, parylene, BCB-based dielectric material, polyimide, other suitable dielectric material, or combinations thereof. In some embodiments, ILD layer 272U include a dielectric material having a dielectric constant that is less than a dielectric constant of silicon dioxide (e.g., k<3.9). In some embodiments, ILD layer 272U includes a dielectric material having a dielectric constant that is less than about 2.5 (i.e., an ELK dielectric material), such as porous silicon oxide, silicon carbide, carbon-doped oxide (e.g., an SiCOH-based material (having, for example, Si—CH₃ bonds)), or combinations thereof, each of which is tuned/configured to have a dielectric constant less than about 2.5. CESL 270U includes a dielectric material that is different than the dielectric material of ILD layer 272U. For example, where ILD layer 272U include a low-k dielectric material (e.g., porous silicon oxide), CESL 270U may include silicon and nitrogen, carbon, oxygen, or combinations thereof, such as silicon nitride, silicon carbonitride, silicon oxycarbonitride, or silicon oxide. In some embodiments, CESL 270U may include metal and oxygen, nitrogen, carbon, or combinations thereof.

In some embodiments, forming insulation structure 268 includes depositing a first dielectric layer having a first thickness (e.g., a CESL) over source/drains 260U, depositing a second dielectric layer having a second thickness (e.g., an ILD layer) over the first dielectric layer, and performing a CMP and/or other planarization process until reaching (exposing) dummy gates 232 (i.e., the first dielectric layer and the second dielectric layer are removed from over gate structures 230). Remainders of the first dielectric layer and the second dielectric layer may provide CESL 270U and ILD layer 272U, respectively. In some embodiments, the planarization process removes hard masks 239, or portion thereof (such as depicted), of dummy gates 232. In some embodiments, the planarization process exposes dummy gate electrodes 238 (e.g., poly gates) of dummy gates 232. The first thickness is less than the second thickness; the first thickness is configured to provide the first dielectric layer partially filling the spaces between gate structures 230; and the second thickness is configured to provide the second dielectric layer filling remainders of the spaces between gate structures 230.

Referring to FIG. 2B and FIG. 3Q, method 100B at block 160 may include removing a dummy gate (e.g., dummy gates 232) of the gate structure (e.g., gate structures 230) to form a gate opening (e.g., gate openings 275). Gate openings 275 may expose channel regions of active region 222. Each gate opening 275 may have sidewalls formed by respective gate spacers 234 (e.g., in the X-Z cross-sectional view) and a bottom formed by active region 222 (e.g., top semiconductor layers 220U) and/or substrate isolation structures 225. In some embodiments, an etching process selectively removes dummy gates 232 without (or negligibly) removing sacrificial layers 215U, sacrificial layers 215L, semiconductor layers 220U, semiconductor layers 220L, protrusion 205L′, bonding/insulation structure 218 (i.e., channel isolation structures), substrate isolation structures 225, gate spacers 234, CESL 270U, ILD layer 272U, or combinations thereof. The etching process is a dry etch, a wet etch, other suitable etch, or combinations thereof. In some embodiments, a patterned mask layer is formed over stacked device structure 200 that exposes dummy gates 232 and covers CESL 270U, ILD layer 272U, gate spacers 244, or combinations thereof during the etching to form gate openings 275.

Referring to FIG. 2B and FIG. 3Q, method 100B at block 165 may include performing a channel release process to form a first channel structure (e.g., semiconductor layers 220U′) and a second channel structure (e.g., semiconductor layers 220L′). The channel release process may include selectively removing sacrificial layers 215U and sacrificial layers 215L exposed by gate openings 275 to form gaps 276U and gaps 276L, respectively. Gaps 276U may be between semiconductor layers 220U and between bottom semiconductor layers 220U and bonding/insulation structure 218 (i.e., channel isolation structures), thereby suspending semiconductor layers 220U in the channel regions. Gaps 276L may be between semiconductor layers 220L, between bottom semiconductor layers 220L and protrusion 205L′, and between top semiconductor layers 220L′ and bonding/insulation structure 218 (i.e., channel isolation structures), thereby suspending semiconductor layers 220L in the channel regions.

In the depicted embodiment, four semiconductor layers 220 (e.g., two semiconductor layers 220U and two semiconductor layers 220L) are vertically stacked along the z-direction and suspended over protrusion 205L′ after the channel release process. Semiconductor layers 220U may provide channels through which current may flow between source/drains 260U, and thus, may be referred to as semiconductor layers 220U′ (corresponding with semiconductor layers 26U), channels 220U′, an upper channel structure, or combinations thereof. Semiconductor layers 220L may provide channels through which current may flow between source/drains 260L, and thus, may be referred to as semiconductor layers 220L′ (corresponding with semiconductor layers 26L), channels 220L′, a lower channel structure, or combinations thereof. For ease of description and understanding, semiconductor layers 220U′ and as semiconductor layers 220L′ may collectively be referred to as semiconductor layers 220′. Further, a respective upper channel structure, a respective lower channel structure, and a respective bonding/insulation structure 218 (i.e., channel isolation structure) therebetween may be referred to as a channel stack of stacked device structure 200. In the depicted embodiment, middle semiconductor layers (e.g., semiconductor layers 26M) are omitted from stacked device structure 200. In some embodiments, stacked device structure 200 may include middle semiconductor layers (i.e., dummy channels) that extend between respective bonding/insulation structures 218. In such embodiments, bonding/insulation structures 218 may be sandwiched between an upper, middle semiconductor layer and a lower, middle semiconductor layer.

Because the disclosed source/drain fabrication techniques described herein provide source/drain recesses 240 with a varying width (e.g., upper widths are greater than lower widths) and thus source/drains with varying width (e.g., source/drains 260U have width w6, which is greater than width w4 of source/drains 260L), upper channels and lower channels may have different lengths. For example, since width w1 is greater than width w3, lengths of semiconductor layers 220L′ may be longer than lengths of semiconductor layers 220U′. In some embodiments, semiconductor layers 220L′ may extend a distance d1 (e.g., along the x-direction) beyond left ends of semiconductor layers 220U′ and a distance d2 (e.g., along the x-direction) beyond right ends of semiconductor layers 220U′. In such embodiments, lengths of semiconductor layers 220L′ may be equal to a sum of a length of semiconductor layers 220U′, distance d1, and distance d2. In other words, a difference in lengths (Δl) of semiconductor layers 220L′ and semiconductor layers 220U′ is a sum of distance d1 and a distance d2.

In some embodiments, the channel release process includes an etching process that selectively etches sacrificial layers 215 without (or negligibly) etching semiconductor layers 220, protrusions 205L′ (15), bonding/insulation structures 218 (17), gate spacers 234 (44), inner spacers 244 (54) (e.g., inner spacers 244U and inner spacers 244L), substrate isolation structures 225, the dielectric layer, or combinations thereof. An etchant may be selected for the etching process that etches silicon germanium (i.e., sacrificial layers 215) at a higher rate than silicon (i.e., semiconductor layers 220 and protrusions 205L′) and dielectric materials (i.e., the etchant has a high etch selectivity with respect to silicon germanium). The etching process is a dry etch, a wet etch, other suitable etching process, or combinations thereof. In some embodiments, before the etching process, an oxidation process may convert sacrificial layers 215 into semiconductor oxide features (e.g., silicon germanium oxide), and the etching process then removes the semiconductor oxide features. In some embodiments, during and/or after removing sacrificial layers 215, an etching process is performed to modify a profile of semiconductor layers 220 to provide target dimensions and/or target shapes thereof. For example, the etching process may provide semiconductor layers 220 with cylindrical-shaped profiles (e.g., nanowires), rectangular-shaped profiles (e.g., nanobars), sheet-shaped profiles (e.g., nanosheets), or any other suitable shaped profile. In some embodiments, semiconductor layers 220 have nanometer-sized dimensions and may be referred to as “nanostructures.” In some embodiments, semiconductor layers 220 have sub-nanometer dimensions and/or other suitable dimensions.

Referring to FIG. 2B and FIG. 3Q, method 100B at block 170 may include forming a gate (e.g., gates 290) over the first channel structure (e.g., semiconductor layers 220U′) and the second channel structure (e.g., semiconductor layers 220L′). Each gate 290 (which corresponds with gate 90) has a respective gate stack 290U (which corresponds with gate stack 90U), which is disposed between respective source/drains 260U, and a respective gate stack 290L (which corresponds with gate stack 90L), which is disposed between respective source/drains 260L. Gate stack 290U includes a gate dielectric 278U (which corresponds with gate dielectric 78U) and a gate electrode 280U (which corresponds with gate electrode 80U), and gate stack 290L includes a gate dielectric 278L (which corresponds with gate dielectric 78L) and a gate electrode 280L (which corresponds with gate electrode 80L). Gate stack 290U is disposed between gate spacers 234, between inner spacers 244U, between semiconductor layers 220U′, and between bottom semiconductor layers 220U′ and bonding/insulation structures 218. Gate stack 290L is disposed between inner spacers 244L, between semiconductor layers 220L′, between top semiconductor layers 220L′ and bonding/insulation structures 218, and between bottom semiconductor layers 220L′ and protrusion 205L′. Gate stack 290U may surround and/or wrap semiconductor layers 220U′ (e.g., in the Y-Z plane), and gate stack 290L may surround and/or wrap semiconductor layers 220L′ (e.g., in the Y-Z plane).

Gate dielectric 278U and gate dielectric 278L each include at least one dielectric gate layer. A composition and/or a configuration of gate dielectric 278U may be the same as or different than a composition and/or a configuration of gate dielectric 278L. In some embodiments, gate dielectric 278U and gate dielectric 278L each include an interfacial layer that includes a dielectric material, such as SiO₂, SiGeOₓ, HfSiO, SiON, other dielectric material, or combinations thereof. In some embodiments, gate dielectric 278U and gate dielectric 278L each include a high-k dielectric layer. The high-k dielectric layer includes a high-k dielectric material, which generally refers to dielectric materials having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr) TiO₃ (BST), Si₃N₄, HfO₂-Al₂O₃, other high-k dielectric material, or combinations thereof. For example, gate dielectric 278U and gate dielectric 278L may each include a hafnium-based oxide (e.g., HfO₂) layer and/or a zirconium-based oxide (e.g., ZrO₂) layer. In some embodiments, the interfacial layer and/or the high-k dielectric layer has a multilayer structure.

Gate electrode 280U and gate electrode 280L are disposed over gate dielectric 278U and gate dielectric 278L, respectively. A composition and/or a configuration of gate electrode 280U may be the same as or different than a composition and/or a configuration of gate electrode 280L. Gate electrode 280U and gate electrode 280L each include at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, gate electrode 280U and/or gate electrode 280L include a work function layer. The work function layer is a conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, gate electrode 280U and/or gate electrode 280L include a bulk layer over the gate dielectric and/or the work function layer. The bulk layer includes a suitable conductive material, such as Al, W, Cu, Ti, Ta, TiN, TaN, polysilicon, other suitable metal(s) and/or alloys thereof, or combinations thereof. In some embodiments, gate electrode 280U and/or gate electrode 280L include a barrier (blocking) layer over the work function layer and/or the gate dielectric. The barrier layer includes a material that prevents or eliminates diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

In some embodiments, forming gate stack 290U and/or gate stack 290L includes depositing gate dielectric layers that partially fill gate openings 275, gaps 276U, gaps 276L, or combinations thereof; depositing gate electrode layers that fill remainders of gate openings 275, gaps 276U, gaps 276L, or combinations thereof; and performing a planarization process to remove portions of the gate dielectric layers and/or portions of the gate electrode layers over insulation structure 268. Gate stack 290U and gate stack 290L may be formed simultaneously, separately, or at least partially simultaneously. In some embodiments, processing may further include etching back gates 290U and forming hard masks 292 (e.g., self-aligned cap (SAC) structures) (which correspond with hard masks 92) over the etched-back gate stacks 290U. Hard masks 292 include a material that is different than over insulation structure 268 and/or subsequently formed insulation layers (e.g., ILD layers and/or CESLs) to achieve etch selectivity. In some embodiments, hard masks 292 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, hard masks 292 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or combinations thereof.

Gate stacks 290U and gate stacks 290L are configured to achieve desired functionality according to design requirements of stacked device structure 200, and gate stacks 290U and gate stacks 290L may have different layers in different device regions. For example, compositions and/or configurations of gate dielectrics 278U and gate dielectrics 278L may be the same or different, and compositions and/or configurations of gate electrodes 280U and gate electrodes 280L may be the same or different. In some embodiments, a number, configuration, materials, or combinations thereof of layers of gate dielectrics 278U corresponding with upper device (e.g., device 14U) and/or upper transistors (e.g., transistors 20U, such as n-type transistors) may be different than a number, configuration, materials, or combinations thereof of layers of gate dielectrics 278L corresponding with lower device (e.g., device 14L) and/or lower transistors (e.g., transistors 20L, such as p-type transistors). In some embodiments, a number, configuration, materials, or combinations thereof of layers of gate electrodes 280U corresponding with upper device (e.g., device 14U) and/or upper transistors (e.g., transistors 20U, such as n-type transistors) may be different than a number, configuration, materials, or combinations thereof of layers of gate electrodes 180L with lower device (e.g., device 14L) and/or lower transistors (e.g., transistors 20L, such as p-type transistors).

Stacked device structure 200 may thus include various transistors, such as transistors T1 (which correspond with transistors 20U) of device 14U and transistors T2 (which correspond with transistors 20L). In the depicted embodiment, transistors T1 are n-type transistors, transistors T2 are p-type transistors, and a device stack DS (which corresponds with device stack 12A or device stack 12B) includes a respective transistor T1 disposed over a respective transistor T2 (i.e., device stack DS provides a CFET). Transistor T1 may include respective channels (e.g., semiconductor layers 220U′), source/drains (e.g., source/drains 260U), and a respective gate (e.g., gate stack 290U); and transistor T2 may include respective channels (e.g., semiconductor layers 220L′), source/drains (e.g., source/drains 260L), and a respective gate (e.g., gate stack 290L). Gate stack 290U is disposed between respective source/drains (e.g., source/drains 260U) along the x-direction, and inner spacers 244U are disposed between gate stacks 290U and their respective source/drains; and gate stacks 290L are disposed between respective source/drains (e.g., source/drain structures 260L) along the x-direction, and inner spacers 244L are disposed between gate stacks 290L and their respective source/drains. Further, gate stacks 290U engage respective channels (e.g., semiconductor layers 220U′), and the respective channels extend between the respective source/drains (e.g., source/drains 260U) along the x-direction, and gate stacks 290L engage respective channels (e.g., semiconductor layers 220L′), and the respective channels extend between the respective source/drains (e.g., source/drains 260L) along the x-direction. In the depicted embodiment, transistor T1 and transistor T2 are GAA transistors. Gate stacks 290U may thus surround their respective channel layers, and along the gate lengthwise direction, each gate stack 290U may include a gate dielectric (e.g., gate dielectric 178U) and a gate electrode (e.g., gate electrode 180U) that surrounds its respective channels. Gate stacks 290L may also surround their respective channel layers, and along the gate lengthwise direction, each gate stack 290L may include a gate dielectric (e.g., gate dielectric 278L) and a gate electrode (e.g., gate electrode 280L) that surrounds its respective channels. In some embodiments, gate stacks 290U and gate stacks 290L may wrap and/or partially surround their respective channel layers (i.e., disposed on at least two sides thereof), such as where transistor T1 and transistor T2 are fork-sheet transistors or other multigate transistors. In some embodiments, transistors T1 are p-type transistors, and transistors T2 are n-type transistors. In some embodiments, transistors T1 and transistors T2 may have different numbers of channels (e.g., a number of semiconductor layers 220U′ may be more or less than a number of semiconductor layers 220L′). In some embodiments, transistors T1 and transistors T2 may have different channel materials (e.g., semiconductor layers 220U′ and semiconductor layers 220L′ may have different compositions (e.g., silicon and silicon germanium, respectively)).

Device stack DS may include a channel stack disposed between source/drain stacks. The channel stack includes semiconductor layers 220U′, semiconductor layers 220L′, and a channel isolation structure (e.g., bonding/insulation structure 218) disposed between semiconductor layers 220U′ and semiconductor layers 220L′. Each source/drain stack includes a respective source/drain 260U, a respective source/drains 260L, and a respective source/drain isolation structure 265 disposed between the respective source/drain 260U and the respective source/drains 260L. Semiconductor layers 220U′ are disposed between source/drains 260U of the source/drain stacks, semiconductor layers 220L′ are disposed between source/drains 260L of the source/drain stacks, and the channel isolation structure (e.g., bonding/insulation structure 218) is disposed between source/drain isolation structures 265 of the source/drain stacks. Implementing the stacked device structure fabrication techniques described herein, stacked device structure 200 (e.g., device stack DS thereof) is provided with source/drains having different widths (e.g., widths of source/drains 260U are greater than widths of source/drains 260L); channels having different lengths (e.g., lengths of semiconductor layers 220U′ are less than lengths of semiconductor layers 220L′); channel isolation structures and source/drain isolation structures having different configurations (e.g., bonding/insulation structures 218 provide the channel isolation structures, CESL 270L/ILD layer 272L provide source/drain isolation structures 265); channel isolation structures and source/drain isolation structures 265 with substantially aligned tops/bottoms along the gate widthwise direction (and/or active region lengthwise direction) (e.g., along the gate widthwise direction (e.g. FIG. 3R), tops of the channel isolation structures and tops of source/drain isolation structures 265 are substantially aligned (e.g., at a same level and/or coplanar), bottoms of the channel isolation structures and bottoms of source/drain isolation structures 265 are substantially aligned (e.g., at a same level and/or coplanar), and the channel isolation structures and source/drain isolation structures 265 have the same thicknesses/heights (e.g., along the z-direction); or combinations thereof. Implementing the stacked device structure fabrication techniques described herein may improve height uniformity of source/drains 260L (e.g., source/drains 260L may have substantially the same height) and eliminates the need for forming dummy source/drains (e.g., temporary placeholders for source/drains 260L), which have been observed to introduce undesired leakage. The disclosed stacked device structure fabrication techniques described herein may thus improve device uniformity and/or device performance. Different embodiments may have different advantages, and no particular advantage is required of any embodiment.

Referring to FIG. 4, in some embodiments, source/drains 260U and/or source/drains 260L may have a multilayer structure. For example, in FIG. 4, source/drains 260L may include a respective undoped semiconductor layer 302, a respective insulation layer 304, and a respective doped semiconductor layer 306. Referring to FIG. 3L and FIG. 4, undoped semiconductor layers 302 may be formed in bottoms of source/drain recesses 240. Undoped semiconductor layers 302 are disposed below bottommost semiconductor layers 220L (e.g., below bottoms thereof). Undoped semiconductor layers 302 are dopant-free (i.e., substantially free of n-type dopants and p-type dopants). For example, no intentional doping is performed when forming undoped semiconductor layers 302. Undoped semiconductor layers 302 may provide high resistance paths at bottoms of source/drains, thereby suppressing leakage current into substrate 205. Undoped semiconductor layers 302 include silicon, germanium, silicon germanium, other suitable semiconductor materials, or combinations thereof. For example, undoped semiconductor layers 302 are dopant-free silicon germanium layers or dopant-free silicon layers. In some embodiments, semiconductor materials having dopant concentrations less than about 5×10¹⁸ cm⁻³ (e.g., about 1×10¹⁸ cm⁻³ to about 5×10¹⁸ cm⁻³) may be considered undoped.

Insulator layers 304 may be formed in source/drain recesses 240 over undoped semiconductor layers 302. Insulator layers 304 partially fill source/drain recesses 240, and insulator layers 304 are also disposed below bottommost semiconductor layers 220L (e.g., below bottoms thereof). Insulator layers 304 include an electrically insulating material, such as a dielectric material, that may reduce unwanted leakage current, such as current that may undesirably flow between doped semiconductor layers 306 through substrate 205. In some embodiments, insulator layers 304 include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. For example, in the depicted embodiment, insulator layers 304 are silicon nitride layers. In some embodiments, insulator layers 304 include a metal-comprising dielectric material, such as a metal oxide material and/or a metal nitride material.

Doped semiconductor layers 306 may be formed in source/drain recesses 240 over insulator layers 304 and/or undoped semiconductor layers 302. Doped semiconductor layers 306 are coupled to edges/ends of semiconductor layers 220L. Doped semiconductor layers 306 include silicon, germanium, silicon germanium, other suitable semiconductor materials, or combinations thereof. In some embodiments, doped semiconductor layers 306 include the same semiconductor material with different constituent concentrations. For example, doped semiconductor layers 306 may include silicon germanium and p-type dopant (e.g., boron and/or gallium). In another example, doped semiconductor layers 306 may include silicon and n-type dopant (e.g., phosphorous and/or arsenic). In some embodiments, doped semiconductor layers 306 include materials and/or dopants that provide compressive stress in semiconductor layers 220L, such as where source/drains 260L belong to p-type transistors. In some embodiments, doped semiconductor layers 306 include materials and/or dopants that provide tensile stress in semiconductor layers 220L, such as where source/drains 260L belong to n-type transistors.

Devices and/or structures described herein, such as stacked device structure 10, device stack 12A, device stack 12B, device 14U, device 14L, transistor 20U, transistor 20L, stacked device structure 200, etc. may be included in a microprocessor, a memory, other IC device, or combinations thereof. In some embodiments, stacked device structure 10 and/or other stacked device structure described herein is a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), complementary metal-oxide semiconductor transistors, bipolar junction transistors (BJTs), laterally diffused MOS (LDMOS) transistors, high voltage transistors, high frequency transistors, other components, or combinations thereof.

The present disclosure provides for many different embodiments. An exemplary method includes receiving a stacked structure that includes a first multilayer stack, a second multilayer stack disposed over the first multilayer stack, and an insulation structure disposed between the first multilayer stack and the second multilayer stack. The method includes forming a first source/drain trench in the second multilayer stack and, after forming dummy sidewall masks in the first source/drain trench, forming a second source/drain trench in the first multilayer stack. The first source/drain trench is disposed over the second source/drain trench. The method includes forming a first source/drain in the second source/drain trench and, after removing the dummy sidewall masks, forming a second source/drain in the first source/drain trench. The second source/drain is disposed over the first source/drain. In some embodiments, forming the first source/drain includes forming a p-doped source/drain and forming the second source/drain includes forming an n-doped source/drain. In some embodiments, the method includes forming the stacked structure, which may include forming a first insulation layer over the first multilayer stack, forming a second insulation layer over the second multilayer stack, and bonding the first insulation layer and the second insulation layer. In such embodiments, the first insulation layer bonded to the second insulation layer may form the insulation structure.

In some embodiments, forming the first source/drain trench includes performing a first source/drain etch that removes a first portion of the second multilayer stack and performing a second source/drain etch that removes a first portion of the first multilayer stack. The first source/drain etch exposes a portion of the insulation structure, and second portions of the second multilayer stack may form sidewalls of the first source/drain trench. The second source/drain etch may expose a substrate (e.g., a protrusion thereof and/or therefrom), and second portions of the first multilayer stack may form sidewalls of the second source/drain trench. The dummy sidewall masks may cover the sidewalls of the first source/drain trench formed by the second portions of the second multilayer stack. In some embodiments, the method further includes removing the exposed portion of the insulation structure, thereby exposing the first portion of the first multilayer stack. In some embodiments, the method further includes, after removing the dummy sidewall masks and before forming the second source/drain, forming a source/drain isolation structure over the first source/drain. In some embodiments, forming the source/drain isolation structure over the first source/drain includes forming a first dielectric layer (e.g., a contact etch stop layer) over the first source/drain, forming a second dielectric layer (e.g., an interlayer dielectric layer) over the first dielectric layer, and etching back the first dielectric layer and the second dielectric layer. In some embodiments, the etching back of the first dielectric layer and the second dielectric layer includes providing the source/drain isolation structure with a height over the first source/drain that equals a thickness of the insulation structure.

Another exemplary method includes receiving a stacked structure that includes a first multilayer stack, a second multilayer stack, and a first insulation structure. The first multilayer stack is disposed over the second multilayer stack, and the first insulation structure is disposed between the first multilayer stack and the second multilayer stack. The method includes forming a source/drain stack in the stacked structure, which may include forming a first portion of a source/drain trench in the first multilayer stack that exposes the first insulation structure. Forming the source/drain stack in the stacked structure may further include, after forming dummy sidewall masks in the first portion of the source/drain trench, extending the source/drain trench into the first insulation structure and the second multilayer stack, such that a second portion of the source/drain trench is in the first insulation structure and a third portion of the source/drain trench is in the second multilayer stack. Forming the source/drain stack in the stacked structure may further include forming a first source/drain in the third portion of the source/drain trench. Forming the source/drain stack in the stacked structure may further include, after removing the dummy sidewall masks from the first portion of the source/drain trench, forming a second insulation structure in the second portion of the source/drain trench over the first source/drain. Forming the source/drain stack in the stacked structure may further include forming a second source/drain in the first portion of the source/drain trench over the second insulation structure. In some embodiments, the first portion of the source/drain trench has a first width, the second portion of the source/drain trench and the third portion of the source/drain trench have a second width, and the second width is less than the first width.

In some embodiments, the method further includes forming the stacked structure, which may include forming a first insulation layer over the first multilayer stack, forming a second insulation layer over the second multilayer stack, and bonding the first insulation layer and the second insulation layer. In such embodiments, the first insulation layer bonded to the second insulation layer may form the first insulation structure. In some embodiments, forming the second insulation structure in the second portion of the source/drain trench over the first source/drain includes depositing a contact etch stop layer (CESL) over the first source/drain, depositing an interlayer dielectric (ILD) layer over the CESL, and etching back the ILD layer and the CESL. The CESL partially fills the source/drain trench, the ILD layer fills a remainder of the source/drain trench, and the etching back removes the ILD layer and the CESL from the first portion of the source/drain trench, such that a remainder of the ILD layer and the CESL fill the second portion of the source/drain trench. In some embodiments, the etching back of the ILD layer and the CESL provides the second insulation structure with a height over the first source/drain that equals a thickness of the first insulation structure.

In some embodiments, forming the dummy sidewall masks includes forming silicon nitride masks along sidewalls of the first portion of the source/drain trench, and the sidewalls of the first portion of the source/drain trench are formed by remaining portions of the first multilayer stack. In some embodiments, forming the dummy sidewall masks includes forming metal oxide masks along sidewalls of the first portion of the source/drain trench, and the sidewalls of the first portion of the source/drain trench are formed by remaining portions of the first multilayer stack. In some embodiments, removing the dummy sidewall masks includes performing an etching process that uses hot phosphoric acid.

An exemplary stacked device structure includes a source/drain stack. The source/drain stack includes a first source/drain structure having a first width and a second source/drain structure having a second width. The second source/drain structure is disposed over the first source/drain structure, and the second width is greater than the first width. The source/drain stack further includes a source/drain isolation structure disposed between the first source/drain structure and the second source/drain structure. In some embodiments, the source/drain isolation structure has a third width that is the same as the first width.

In some embodiments, the stacked device structure includes a channel stack adjacent to the source/drain stack. The channel stack includes a first channel and a second channel, and the second channel is disposed over the first channel. The first channel is adjacent to the first source/drain structure. The second channel adjacent to the second source/drain structure. The first channel has a first length, the second channel has a second length, and the second length is less than the first length. The channel stack further includes an isolation structure disposed between the first channel and the second channel. In some embodiments, a first configuration of the isolation structure is different than a second configuration of the source/drain isolation structure. In some embodiments, the isolation structure is a bonding structure that includes at least two portions having different compositions.

An exemplary source/drain patterning technique includes bonding a first multilayer stack, which is to be processed to form an upper device of a device stack (e.g., an upper transistor), and a second multilayer stack, which is to be processed to form a lower device of the device stack (e.g., a lower transistor). The first multilayer stack and the second multilayer stack may be homogenously or heterogeneously bonded by electrically insulating layers, such as dielectric layers. In some embodiments, a stacked structure includes the first multilayer stack, the second multilayer stack, and a bonding structure therebetween, and the bonding structure provides an insulation layer (which may include at least two different layers and/or at least two different material portions) between the first multilayer stack and the second multilayer stack.

The source/drain patterning technique further includes a two-step source/drain etch, and the stacked structure (e.g., including a bonding structure that provides an insulation layer between the first multilayer stack and the second multilayer stack) in combination with the two-step source/drain etch may facilitate self-aligned formation of a source/drain sidewall mask. The two-step source/drain etch may include a first source/drain etch (e.g., an upper source/drain etch) to form first source/drain recesses (e.g., upper source/drain recesses) in the first multilayer stack. The first source/drain etch may stop upon reaching the insulation layer between the first multilayer stack and the second multilayer stack. The first source/drain etch may remove first portions of the first multilayer stack (e.g., those disposed in source/drain regions), the first source/drain recesses may have sidewalls formed by second portions of the first multilayer stack (e.g., those disposed in channel regions and/or having gate structures disposed thereon), and the first source/drain recesses may have bottoms formed by the insulation layer.

The source/drain patterning technique further includes forming source/drain sidewall masks (e.g., dummy, sacrificial sidewalls) in the first source/drain recesses. The source/drain sidewall masks cover sidewalls of the first source/drain recesses (e.g., formed by the second portions of the first multilayer stack). The source/drain sidewall masks may further cover sidewalls of gate structures, such as those disposed over the second portions of the first multilayer stack. Because bottoms of the first source/drain recesses are formed by the insulation layer, the source/drain sidewall masks terminate at a same level of the stacked structure. For example, bottoms of the source/drain sidewall masks are located the same distance from a bottom of the stacked structure (e.g., at a top surface of the insulation layer). The source/drain sidewall masks may interface with the insulation layer. In some embodiments, the source/drain sidewall masks are formed by depositing and etching a mask material. In some embodiments, the source/drain sidewall masks are formed of a dielectric material(s).

The two-step source/drain etch may further include a second source/drain etch (e.g., a lower source/drain etch) to form second source/drain recesses (e.g., lower source/drain recesses) in the second multilayer stack after forming the source/drain sidewall masks. The second source/drain etch may remove portions of the insulation layer exposed by the first source/drain recesses (a width of which is reduced by the source/drain sidewall masks formed therein) and first portions of the second multilayer stack (e.g., those disposed in source/drain regions) exposed by the first source/drain recesses. The second source/drain recesses may have sidewalls formed by second portions of the second multilayer stack (e.g., those disposed in channel regions and/or having gate structures disposed thereon), and the second source/drain recesses may have bottoms formed by a substrate. In some embodiments, first inner spacers (e.g., upper inner spacers) are formed before forming the source/drain sidewall masks, and the first inner spacers may form portions of the sidewalls of the first source/drain recesses (and thus the source/drain side wall masks may cover the first inner spacers). In some embodiments, second inner spacers (e.g., lower inner spacers) are formed after forming the second source/drain recesses.

The source/drain patterning technique further includes forming first source/drains (e.g., lower source/drains) in the second source/drain recesses, removing the source/drain sidewall masks after forming the first source/drains, forming a source/drain isolation structure (e.g., a contact etch stop layer (CESL) and an interlayer dielectric (ILD) layer) over the first source/drains, and forming second source/drains (e.g., upper source/drains) over the source/drain isolation structure and in the first source/drain recesses. In some embodiments, tops of the first source/drains are a distance below a top of the insulation layer. In some embodiments, the distance is substantially the same as a thickness of the insulation layer. In some embodiments, the distance is less than or greater than a thickness of the insulation layer. In some embodiments, the source/drain isolation structure does not extend above the top of the insulation layer.

The source/drain patterning technique may result in the first source/drains and the second source/drains having different widths. For example, widths of the first source/drains (e.g., lower source/drains) may be less than widths of the second source/drains (e.g., upper source/drains) because the source/drain sidewall masks provide a smaller patterning window for forming the second source/drain recesses. The source/drain patterning technique may also result in the first device and the second device having different channel lengths. For example, lengths of first channels of the first device (e.g., upper channels of the upper device) may be less than lengths of second channels of the second device (e.g., lower channels of the lower device) because widths of the first source/drain recesses may be greater than widths of the second source/drain recesses as a result of using the source/drain sidewall masks as source/drain etch masks. The source/drain patterning technique may also provide different isolation/insulation structures in source/drain regions and channel regions (and/or gate regions), such as source/drain isolation structures between the first source/drains and the second source/drains and bonding structures (e.g., the insulation layer) between the first channels and the second channels (and/or between first gates (e.g., upper gates) and second gates (e.g., lower gates)). In some embodiments, thicknesses of the source/drain isolation structures are about the same as (i.e., about equal to) a thickness of the insulation layer (e.g., the bonding structure).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
receiving a stacked structure that includes a first multilayer stack, a second multilayer stack disposed over the first multilayer stack, and an insulation structure disposed between the first multilayer stack and the second multilayer stack;
forming a first source/drain trench in the second multilayer stack;
after forming dummy sidewall masks in the first source/drain trench, forming a second source/drain trench in the first multilayer stack;
forming a first source/drain in the second source/drain trench; and
after removing the dummy sidewall masks, forming a second source/drain in the first source/drain trench.

2. The method of claim 1, further comprising forming the stacked structure, wherein the forming the stacked structure includes:
forming a first insulation layer over the first multilayer stack;
forming a second insulation layer over the second multilayer stack; and
bonding the first insulation layer and the second insulation layer, wherein the first insulation layer bonded to the second insulation layer forms the insulation structure.

3. The method of claim 1, wherein:
the forming the first source/drain trench includes performing a first source/drain etch that removes a first portion of the second multilayer stack, wherein the first source/drain etch exposes a portion of the insulation structure, second portions of the second multilayer stack form sidewalls of the first source/drain trench, and the dummy sidewall masks cover the sidewalls of the first source/drain trench formed by the second portions of the second multilayer stack; and
the forming the second source/drain trench includes performing a second source/drain etch that removes a first portion of the first multilayer stack.

4. The method of claim 3, further comprising removing the exposed portion of the insulation structure, thereby exposing the first portion of the first multilayer stack.

5. The method of claim 1, further comprising, after removing the dummy sidewall masks and before forming the second source/drain, forming a source/drain isolation structure over the first source/drain.

6. The method of claim 5, wherein the forming the source/drain isolation structure over the first source/drain includes:
forming a first dielectric layer over the first source/drain;
forming a second dielectric layer over the first dielectric layer; and
etching back the first dielectric layer and the second dielectric layer.

7. The method of claim 6, wherein the etching back the first dielectric layer and the second dielectric layer includes providing the source/drain isolation structure with a height over the first source/drain that equals a thickness of the insulation structure.

8. The method of claim 1, wherein:
the forming the first source/drain includes forming a p-doped source/drain; and
the forming the second source/drain includes forming an n-doped source/drain.

9. A method comprising:
receiving a stacked structure that includes a first multilayer stack, a second multilayer stack, and a first insulation structure, wherein the first multilayer stack is disposed over the second multilayer stack and the first insulation structure is disposed between the first multilayer stack and the second multilayer stack; and
forming a source/drain stack in the stacked structure by:
forming a first portion of a source/drain trench in the first multilayer stack that exposes the first insulation structure,
after forming dummy sidewall masks in the first portion of the source/drain trench, extending the source/drain trench into the first insulation structure and the second multilayer stack, such that a second portion of the source/drain trench is in the first insulation structure and a third portion of the source/drain trench is in the second multilayer stack,
forming a first source/drain in the third portion of the source/drain trench,
after removing the dummy sidewall masks from the first portion of the source/drain trench, forming a second insulation structure in the second portion of the source/drain trench, and
forming a second source/drain in the first portion of the source/drain trench.

10. The method of claim 9, wherein:
the first portion of the source/drain trench has a first width; and
the second portion of the source/drain trench and the third portion of the source/drain trench have a second width, wherein the second width is less than the first width.

11. The method of claim 9, further comprising forming the stacked structure, wherein the forming the stacked structure includes:
forming a first insulation layer over the first multilayer stack;
forming a second insulation layer over the second multilayer stack; and
bonding the first insulation layer and the second insulation layer, wherein the first insulation layer bonded to the second insulation layer forms the first insulation structure.

12. The method of claim 9, wherein the forming the second insulation structure in the second portion of the source/drain trench over the first source/drain includes:
depositing a contact etch stop layer (CESL) over the first source/drain, wherein the CESL partially fills the source/drain trench;
depositing an interlayer dielectric (ILD) layer over the CESL, wherein the ILD layer fills a remainder of the source/drain trench; and
etching back the ILD layer and the CESL, such that the ILD layer and the CESL are removed from the first portion of the source/drain trench and a remainder of the ILD layer and the CESL fill the second portion of the source/drain trench.

13. The method of claim 12, wherein the etching back of the ILD layer and the CESL provides the second insulation structure with a height over the first source/drain that equals a thickness of the first insulation structure.

14. The method of claim 9, wherein the forming the dummy sidewall masks includes forming silicon nitride masks along sidewalls of the first portion of the source/drain trench, wherein the sidewalls of the first portion of the source/drain trench are formed by remaining portions of the first multilayer stack.

15. The method of claim 9, wherein the forming the dummy sidewall masks includes forming metal oxide masks along sidewalls of the first portion of the source/drain trench, wherein the sidewalls of the first portion of the source/drain trench are formed by remaining portions of the first multilayer stack.

16. The method of claim 9, wherein the removing the dummy sidewall masks includes performing an etching process that uses hot phosphoric acid.

17. A stacked device structure comprising:
a source/drain stack that includes:
a first source/drain structure having a first width;
a second source/drain structure having a second width, wherein the second source/drain structure is disposed over the first source/drain structure and the second width is greater than the first width; and
a source/drain isolation structure disposed between the first source/drain structure and the second source/drain structure.

18. The stacked device structure of claim 17, further comprising:
a channel stack that includes:
a first channel adjacent to the first source/drain structure, wherein the first channel has a first length;
a second channel adjacent to the second source/drain structure, wherein the second channel is disposed over the first channel and the second channel has a second length that is less than the first length; and
an isolation structure disposed between the first channel and the second channel, wherein a first configuration of the isolation structure is different than a second configuration of the source/drain isolation structure.

19. The stacked device structure of claim 18, wherein the isolation structure is a bonding structure that includes at least two portions having different compositions.

20. The stacked device structure of claim 17, wherein the source/drain isolation structure has a third width, wherein the third width is the same as the first width.
